(19) United States
(12) Patent Application Publication
(10) Pub. No.: US 2020/0064416 A1
(43) Pub. Date: Feb. 27, 2020

(54) MAGNETIC SENSOR

(71) Applicant: Panasonic Intellectual Property Management Co., Ltd., Osaka (JP)

(72) Inventors: HIDEAKI FUJIURA, Osaka (JP); TAKUYA TOMIDA, Kanagawa (JP); RYO OSABE, Osaka (JP)

(21) Appl. No.: 16/612,417

(22) PCT Filed: May 18, 2018
(86) PCT No.: PCT/JP2018/019216

§ 371 Date: Nov. 11, 2019

(30) Foreign Application Priority Data
May 29, 2017 (JP) 2017-105309

(51) Int. Cl. G01R 33/09; G01D 5/244; H01L 43/06; H01L 43/08; H01L 23/00

(52) U.S. Cl. CPC G01R 33/09; G01D 5/244; H01L 43/06; H01L 2224/73265; H01L 24/03; H01L 2224/48247; H01L 43/08

(57) ABSTRACT

The present disclosure provides a magnetic sensor with improved accuracy or reliability. The magnetic sensor includes a first magnetism detection element that outputs a first detection signal, a second magnetism detection element that outputs a second detection signal, and a detection circuit that receives the first and second detection signals. The detection circuit corrects the first detection signal for each section in a ( 1/16n) period of the first detection signal, when n is a natural number. With this configuration, the magnetic sensor has high accuracy or high reliability, and therefore is useful as, for example, a magnetic sensor used for detecting a steering angle and the like of a vehicle.

### TECHNICAL FIELD

The present disclosure relates to a magnetic sensor used to, for example, detect a steering angle of a vehicle.

### BACKGROUND ART

Conventionally, there is a known magnetic sensor that detects a steering angle even while an ignition switch is turned OFF. Note that PTLs 1 to 3 have been known as prior art literature related to such a magnetic sensor, for example.

Furthermore, there is a known magnetic sensor that detects rotation of an object, which includes, for example, a steering angle, using a magnetic resistance element. PTLs 4 to 6 have been known as prior art literature related to such a magnetic sensor, for example.

Furthermore, there is a known magnetic sensor that includes a magnetic-field generation unit, and diagnoses the sensor based on a magnetic field generated by this magnetic-field generation unit. PTLs 7 and 8 have been known as prior art literature related to such a magnetic sensor, for example.

Furthermore, there is a known magnetic sensor configured by combining a magnetic resistance element with a Hall element. PTLs 9 and 10 have been known as prior art literature related to such a magnetic sensor, for example.

Furthermore, there is a known magnetic sensor provided with two detection systems to improve redundancy of the sensor. PTLs 11 to 13 have been known as prior art literature related to such a magnetic sensor, for example.

Furthermore, there is a known magnetic sensor that detects an external magnetic field using a magnetic resistance film formed from an NiFe alloy. PTLs 14 to 17 have been known as prior art literature related to such a magnetic sensor, for example.

Furthermore, there is a known magnetic sensor configured with a single package in which two sensors are stacked in a vertical direction. PTLs 18 to 22 have been known as prior art literature related to such a magnetic sensor, for example.

Furthermore, there is a known position detection device that detects a position of a shift lever using a magnetic sensor. PTLs 23 to 25 have been known as prior art literature related to such a position detection device, for example.

Furthermore, there is a known rotation detection device that uses two sets of a magnetic sensor and a magnet. PTLs 26 to 27 have been known as prior art literature related to such a position detection device, for example.

Furthermore, there is a known magnetic sensor having a plurality of resins for sealing and bonding a magnetic resistance element, for example. PTLs 28 to 30 have been known as prior art literature related to such a position detection device, for example.

Furthermore, there is a known rotation detection device that uses a magnetic sensor and a magnet. In the rotation detection device, to correct an output, disposition of a magnetic sensor that calculates a measurement angle using a high order polynomial based on a value stored in a memory, or disposition of a sensor that compensates an error in the output is improved. PTLs 31 and 32 have been known as prior art literature related to such a position detection device, for example.

### CITATION LIST

### Patent Literatures

### PTL 1: Unexamined Japanese Patent Publication No. 2015-116964

### PTL 2: International Publication WO 2014/148087

### PTL 3: Unexamined Japanese Patent Publication No. 2002-213944

### PTL 4: Unexamined Japanese Patent Publication No. 2014-209124

### PTL 5: Japanese Patent Publication No. 5708986

### PTL 6: Unexamined Japanese Patent Publication No. 2007-155668

### PTL 7: Japanese Patent Publication No. 5620989

### PTL 8: Unexamined Japanese Patent Publication No. 6-310776

### PTL 9: Japanese Patent Publication No. 4138952

### PTL 10: Japanese Patent Publication No. 5083281

### PTL 11: Japanese Patent Publication No. 3474096

### PTL 12: Japanese Patent Publication No. 4863953

### PTL 13: Japanese Patent Publication No. 5638900

### PTL 14: Examined Japanese Patent Publication No. 4-26227

### PTL 15: Unexamined Japanese Patent Publication No. 2004-172430

### PTL 16: Unexamined Japanese Patent Publication No. 2015-082633

### PTL 17: Unexamined Japanese Patent Publication No. 2015-108527

### PTL 18: Japanese Patent Publication No. 5961777

### PTL 19: US 2015/0198678 A

PTL 20: U.S. Pat. No. 9,151,809
PTL 21: U.S. Pat. No. 8,841,776
PTL 22: U.S. Pat. No. 7,906,961

### PTL 23: Unexamined Japanese Patent Publication No. 2006-234495

### PTL 24: Unexamined Japanese Patent Publication No. 2007-333489

### PTL 25: Japanese Translation of PCT International Application Publication No. 2005-521597

### PTL 26: Japanese Patent Publication No. 5062450

### PTL 27: Japanese Patent Publication No. 5062449

### PTL 28: Unexamined Japanese Patent Publication No. 2015-38507

### PTL 29: Unexamined Japanese Patent Publication No. 2015-41701

### PTL 30: Unexamined Japanese Patent Publication No. 2014-86677

### PTL 31: Unexamined Japanese Patent Publication No. 2009-150795

### PTL 32: Unexamined Japanese Patent Publication No. 2011-158488

### SUMMARY OF THE INVENTION

However, conventional magnetic sensors described above are insufficient to satisfy an increasing demand for high accuracy and high reliability.

Accordingly, the present disclosure provides a magnetic sensor with improved accuracy or reliability.

In order to solve the above-described problems, an invention according to the present disclosure includes a first magnetism detection element that outputs a first detection signal, a second magnetism detection element that outputs a second detection signal, and a detection circuit that receives the first and second signals. When n is a natural number, the detection circuit is configured to correct the first signal for each section in a ( 1/16n) period of the first signal.

A magnetic sensor of the present disclosure has high accuracy or high reliability, and therefore is useful as, for example, a magnetic sensor used for detecting a steering angle and the like of a vehicle.

### BRIEF DESCRIPTION OF DRAWINGS

FIG. 1 is a block diagram illustrating a magnetic sensor according to a first exemplary embodiment.

FIG. 2A is a schematic diagram illustrating a first rotation detection device using the magnetic sensor.

FIG. 2B is a schematic diagram illustrating an example of a control system using the first rotation detection device.

FIG. 2C is a schematic diagram illustrating a second rotation detection device using the magnetic sensor.

FIG. 2D is a schematic diagram illustrating the second rotation detection device using the magnetic sensor.

FIG. 2E is a schematic diagram illustrating other magnets included in the second rotation detection device.

FIG. 2F is a schematic diagram illustrating still other magnets included in the second rotation detection device.

FIG. 3 is an explanatory view of a first operation of a detection circuit of the magnetic sensor.

FIG. 4 is an explanatory view of a second operation of the detection circuit of the magnetic sensor.

FIG. 5 is an explanatory view of a third operation of the detection circuit of the magnetic sensor.

FIG. 6 is an explanatory view of a method for detecting rotation of the magnetic sensor.

FIG. 7A is an explanatory view of a fourth operation of the detection circuit of the magnetic sensor, and is a flowchart illustrating an operation of automatic correction circuit 70e.

FIG. 7B is an explanatory view of the fourth operation of the detection circuit of the magnetic sensor, and is a conceptual view illustrating a correction operation.

FIG. 7C is a waveform chart illustrating an output of the magnetic sensor.

FIG. 7D is an explanatory view of still another operation of the detection circuit of the magnetic sensor.

FIG. 8 is a block diagram illustrating a magnetic sensor according to a second exemplary embodiment.

FIG. 9 is a top view of a magnetic resistance element and a detection circuit.

FIG. 10 is a front view of the magnetic sensor.

FIG. 11 is a front view of a magnetic sensor according to a first modification of the present exemplary embodiment.

FIG. 12 is a top view of the magnetic sensor.

FIG. 13 is a front view of still another magnetic sensor of the present exemplary embodiment.

FIG. 14 is a front view of still another magnetic sensor of the present exemplary embodiment.

FIG. 15 is a perspective view of the magnetic sensor in FIG. 13.

FIG. 16 is another perspective view of the magnetic sensor in FIG. 15.

FIG. 17 is a front view of a magnetic resistance element in FIG. 8.

FIG. 18 is a cross-sectional view of the magnetic resistance element in FIG. 17 taken along line XVIII-XVIII.

FIG. 19A is a top view of a magnetic sensor according to a third exemplary embodiment.

FIG. 19B is a front view of the magnetic sensor.

FIG. 19C is a side view of the magnetic sensor.

FIG. 20A is an explanatory view of an operation of the magnetic sensor when a magnet is disposed on a left side of the magnetic sensor.

FIG. 20B is an explanatory view of a displacement position of the magnet in the magnetic sensor and a magnetic vector, as well as the displacement position of the magnet in the magnetic sensor and an output of the magnetic sensor.

FIG. 21A is an explanatory view of the operation of the magnetic sensor when the magnet is disposed on a right side of the magnetic sensor.

FIG. 21B is an explanatory view of a displacement position of the magnet in the magnetic sensor and a magnetic vector, as well as the displacement position of the magnet in the magnetic sensor and the output of the magnetic sensor.

FIG. 22 is a perspective view of a detection device according to the third exemplary embodiment.

FIG. 23A is a top view of the detection device.

FIG. 23B is a view illustrating an output of a Hall element according to the detection device.

FIG. 24 is a block diagram of the magnetic sensor included in the detection device.

FIG. 25 is an explanatory view of a manufacturing method of still another magnetic sensor according to the present exemplary embodiment.

FIG. 26 is an explanatory view of the manufacturing method of the magnetic sensor.

FIG. 27 is an explanatory view of the manufacturing method of the magnetic sensor.

FIG. 28 is an explanatory view of the manufacturing method of the magnetic sensor.

FIG. 29 is an explanatory view of the manufacturing method of the magnetic sensor.

FIG. 30 is an explanatory view of the manufacturing method of the magnetic sensor.

FIG. 31 is an explanatory view of the manufacturing method of the magnetic sensor.

FIG. 32 is a perspective view of the magnetic sensor.

FIG. 33 is a perspective view of a detection device according to a fourth exemplary embodiment.

FIG. 34A is a top view of a part of the detection device.

FIG. 34B is a perspective view of a detection device of a first modification according to the fourth exemplary embodiment.

FIG. 34C is a top view of a part of the detection device.

FIG. 34D is a perspective view of a detection device of a second modification according to the fourth exemplary embodiment.

FIG. 34E is a top view of a part of the detection device.

FIG. 34F is a perspective view of a detection device of a third modification according to the fourth exemplary embodiment.

FIG. 34G is a top view of a part of the detection device.

FIG. 35 is a front view of a magnetic sensor according to a fourth modification of the fourth exemplary embodiment.

FIG. 36 is a front view of a magnetic sensor according to a fifth modification of the fourth exemplary embodiment.

FIG. 37 is a front view of a magnetic sensor according to a sixth modification of the fourth exemplary embodiment.

FIG. 38 is a front view of a magnetic sensor according to a seventh modification of the fourth exemplary embodiment.

FIG. 39 is a front view of a magnetic sensor according to an eighth modification of the fourth exemplary embodiment.

FIG. 40 is a front view of a magnetic sensor according to a ninth modification of the fourth exemplary embodiment.

### DESCRIPTION OF EMBODIMENTS

Hereinafter, magnetic sensors according to exemplary embodiments of the present disclosure will be described with reference to the drawings.

### First Exemplary Embodiment

### (Magnetic Sensor)

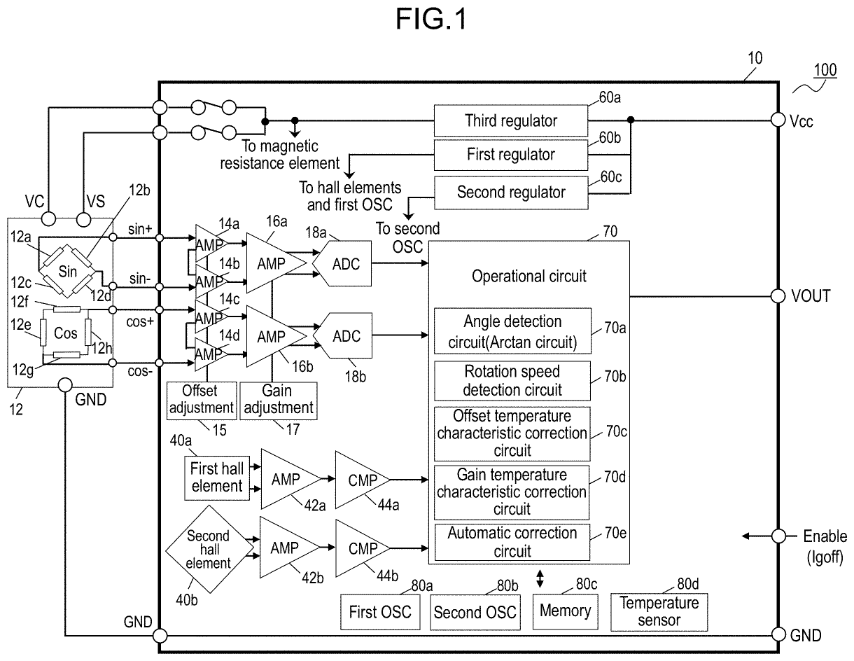

FIG. 1 is a block diagram illustrating a magnetic sensor according to a first exemplary embodiment.

Magnetic sensor 100 includes magnetic resistance element 12 and detection circuit 10 electrically connected to magnetic resistance element 12.

Magnetic resistance element 12 includes first sine magnetic resistance element 12a, second sine magnetic resistance element 12b, third sine magnetic resistance element 12c, and fourth sine magnetic resistance element 12d. Magnetic resistance element 12 further includes first cosine magnetic resistance element 12e, second cosine magnetic resistance element 12f, third cosine magnetic resistance element 12g, and fourth cosine magnetic resistance element 12h. Each magnetic resistance element is a magnetic resistance effect element that is mounted on a substrate such as silicon and contains an iron-nickel alloy, and electric resistance of the magnetic resistance element varies according to a change in direction and magnitude of a magnetic field given from the outside.

First sine magnetic resistance element 12a to fourth sine magnetic resistance element 12d configure first bridge circuit WB1. In other words, first bridge circuit WB1 is formed by a circuit including first sine magnetic resistance element 12a and third sine magnetic resistance element 12c connected in series and a circuit including second sine magnetic resistance element 12b and fourth sine magnetic resistance element 12d connected in series, the circuits being connected in parallel. One end of first bridge circuit WB1 is connected to potential VS, and the other end of first bridge circuit WB1 is connected to ground (GND in FIG. 1).

First cosine magnetic resistance element 12e to fourth cosine magnetic resistance element 12h configure second bridge circuit WB2. In other words, second bridge circuit WB2 is formed by a circuit including first cosine magnetic resistance element 12e and third cosine magnetic resistance element 12g connected in series and a circuit including second cosine magnetic resistance element 12f and fourth cosine magnetic resistance element 12h connected in series, the circuits being connected in parallel. One end of second bridge circuit WB2 is connected to potential VC, and the other end of second bridge circuit WB2 is connected to ground (GND in FIG. 1).

Herein, first bridge circuit WB1 is disposed while being rotated with respect to second bridge circuit WB2 by 45 degrees. In other words, second bridge circuit WB2 is disposed while being rotated with respect to first bridge circuit WB1 by 45 degrees.

Herein, magnetic sensor 100 is disposed near a magnet that is connected to a rotary member (e.g., a steering shaft) through a gear wheel and the like, the rotary member being a measurement target. With this configuration, a resistance value of each magnetic resistance element varies according to a change in external magnetic field (or a rotation magnetic field) that is given from this magnet. Therefore, a connecting part of first sine magnetic resistance element 12a and third sine magnetic resistance element 12c and a connecting part of second sine magnetic resistance element 12b and fourth sine magnetic resistance element 12d output two sine wave signals, first sine magnetic resistance element 12a to fourth sine magnetic resistance element 12d configuring first bridge circuit WB1. Those two sine waves respectively have phases that are mutually shifted by 180 degrees. At the same time, a connecting part of first cosine magnetic resistance element 12e and third cosine magnetic resistance element 12g and a connecting part of second cosine magnetic resistance element 12f and fourth cosine magnetic resistance element 12h output two cosine wave signals, first cosine magnetic resistance element 12e to fourth cosine magnetic resistance element 12h configuring second bridge circuit WB2. Those two cosine waves respectively have phases that are mutually shifted by 180 degrees. Note that, first bridge circuit WB1 is disposed while being rotated with respect to second bridge circuit WB2 by 45 degrees, whereby first bridge circuit WB1 provides the sine wave signal and second bridge circuit WB2 provides the cosine wave signal.

Herein the two signals output from first bridge circuit WB1 are denoted as a +sin signal and a −sin signal, and the two signals output from second bridge circuit WB2 are denoted as a +cos signal and a −cos signal.

Detection circuit 10 receives the +sin signal, the −sin signal, the +cos signal, and the −cos signal, and performs various signal processes such as amplification and analog-to-digital (AD) conversion on the +sin signal, the −sin signal, the +cos signal, and the −cos signal. Note that in FIG. 1, the +sin signal, the −sin signal, the +cos signal, and the −cos signal are denoted as sin+, sin−, cos+, and cos−, respectively.

Note that a signal from each magnetic resistance element can be described as a “first rotation signal”.

Hereinafter, a configuration and an operation of detection circuit 10 will be specifically described.

First amplifier 14a amplifies the +sin signal.

Second amplifier 14b amplifies the −sin signal.

Third amplifier 14c amplifies the +cos signal.

Fourth amplifier 14d amplifies the −cos signal.

Offset adjustment circuit 15 is connected to input stages of first amplifier 14a, second amplifier 14b, third amplifier 14c, and fourth amplifier 14d, and adjusts a midpoint potential difference between the +sin signal and −sin signal and a midpoint potential difference between the +cos signal and −cos signal to be 0.

First differential amplifier 16a differentially amplifies the +sin signal and the −sin signal output from first bridge circuit WB1 to generate a sin signal having double amplitude. This sin signal can be described as a “first signal”.

Note that first bridge circuit WB1 and the signal from first bridge circuit WB1 can be described as a first magnetic resistance element and a first detection signal, respectively.

Second differential amplifier 16b differentially amplifies the +cos signal and the −cos signal output from second bridge circuit WB2 to generate a cos signal having double amplitude. This cos signal can be described as a “second signal”.

Note that second bridge circuit WB2 and the signal from second bridge circuit WB2 can be described as a second magnetic resistance element and a second detection signal, respectively.

Gain adjustment circuit 17 is connected to first differential amplifier 16a and second differential amplifier 16b, and adjusts gains of the amplifiers such that amplitude of each of the sin signal and the cos signal after differential amplification becomes predetermined amplitude.

With this configuration, it is unnecessary to adjust the offset and the gain for each amplifier stage. This can adjust the signal by adjusting the offset once and adjusting the gain once. This particularly contributes to downsizing of the circuit.

Note that the offset and gain adjustment can be described below with different expression, for example.

A method for correcting magnetic sensor 100 of the present exemplary embodiment includes a first step for amplifying outputs of bridge circuits WB1, WB2, a second step for correcting offsets of the outputs of bridge circuits WB1, WB2, a third step for amplifying outputs with the corrected offsets, and a fourth step for correcting gains of the outputs with the corrected offsets.

First AD converter 18a performs AD conversion on a signal from first differential amplifier 16a with a predetermined sampling period, and outputs the converted signal as a sin signal (digital signal).

Second AD converter 18b performs A/D conversion on a signal from second differential amplifier 16b with the predetermined sampling period, and outputs the converted signal as a cos signal (digital signal).

First Hall element 40a is a Hall element having detection sensitivity to a magnetic field in a direction perpendicular to or parallel to a circuit board provided with detection circuit 10, and detects changes in direction and magnitude of the above-described external magnetic field (rotation magnetic field) to output the detection signal.

Second Hall element 40b is a Hall element having detection sensitivity to the magnetic field in the direction perpendicular to or parallel to the circuit board provided with detection circuit 10, and detects changes in direction and magnitude of the above-described external magnetic field (rotation magnetic field) to output the detection signal.

Note that a signal from each Hall element can be described as a “second rotation signal”.

First amplifier 42a amplifies the signal from first Hall element 40a.

Second amplifier 42b amplifies the signal from second Hall element 40b.

First comparator 44a converts a signal from first amplifier 42a into a first pulse signal that is a rectangular wave signal.

Second comparator 44b converts a signal from second amplifier 42b into the first pulse signal that is the rectangular wave signal.

Herein, first Hall element 40a is disposed while being rotated by 90 degrees with respect to second Hall element 40b (in other words, second Hall element 40b is disposed while being rotated by 90 degrees with respect to first Hall element 40a). Hence, the first pulse signal (that is, first Hall element 40a) and the second pulse signal (that is, the signal from second Hall element 40b) are signals each having a phase difference by 90 degrees from each other.

First regulator 60b supplies potential (first potential) to first oscillator 80a. First regulator 60b also supplies the potential (first potential) to first Hall element 40a, second Hall element 40b, and the amplifiers and other circuits that process the signals from the Hall elements in detection circuit 10.

Second regulator 60c supplies the potential (first potential) to second oscillator 80b. Second regulator 60c supplies potential used for an intermittent operation of the Hall elements (details will be described later).

Third regulator 60a supplies potential (first potential) to magnetic resistance element 12 and the amplifiers and other circuits that process the signal from magnetic resistance element 12 in detection circuit 10.

Operational circuit 70 includes angle detection circuit 70a, rotation speed detection circuit 70b, offset temperature characteristic correction circuit 70c, and gain temperature characteristic correction circuit 70d.

Angle detection circuit 70a detects a rotation angle of the above magnet from the sin signal (digital signal), the cos signal (digital signal), the first pulse signal, and the second pulse signal, and outputs signal (Vout). Specifically, angle detection circuit 70a performs an arctan operation on the sin signal and the cos signal to detect the rotation angle. Angle detection circuit 70a outputs an angle signal indicating the rotation angle after the arctan operation. In other words, angle detection circuit 70a receives the sin signal (first signal) and the cos signal (second signal). Angle detection circuit 70a converts the sin signal (first signal) and the cos signal (second signal) to generate and output the angle signal (that can be described as a third signal).

Note that angle detection circuit 70a may be described as an arctan circuit.

Rotation speed detection circuit 70b measures the rotation speed of the above magnet based on the first pulse signal and the second pulse signal. A method for measuring the rotation speed will be described later.

Offset temperature characteristic correction circuit 70c corrects a DC offset produced in the sin signal (digital signal) or the cos signal (digital signal) due to a variation in resistance of each magnetic resistance element. A correction method will be described later.

Gain temperature characteristic correction circuit 70d corrects an offset of a gain (amplitude) produced in the sin signal (digital signal) or the cos signal (digital signal) due to a change in temperature of each magnetic resistance element. This method measures how the sin signal (digital signal) or the cos signal (digital signal) changes according to the temperature in advance, and retains the measured value in the memory in detection circuit 10. The measured value in the memory is read based on temperature information obtained from temperature sensor 80d. The measured value read from the memory is superimposed on the sin signal (digital signal) or the cos signal (digital signal). The correction of the temperature offset is thus achieved.

First oscillator 80a is an oscillation circuit for generating an internal clock used in detection circuit 10. The internal clock generated by first oscillator 80a is used for detection in magnetic resistance element 12 and each Hall element.

Second oscillator 80b is an oscillation circuit for generating another internal clock used in detection circuit 10.

Herein, when a signal (that is, a first clock signal) generated by first oscillator 80a has a first frequency and a signal (that is, a second clock signal) generated by second oscillator 80b has a second frequency, the second frequency is lower than the first frequency.

Memory 80c stores the rotation speed measured by rotation speed detection circuit 70b described above and the measured value used for correcting the temperature offset, for example.

### (First Rotation Detection Device)

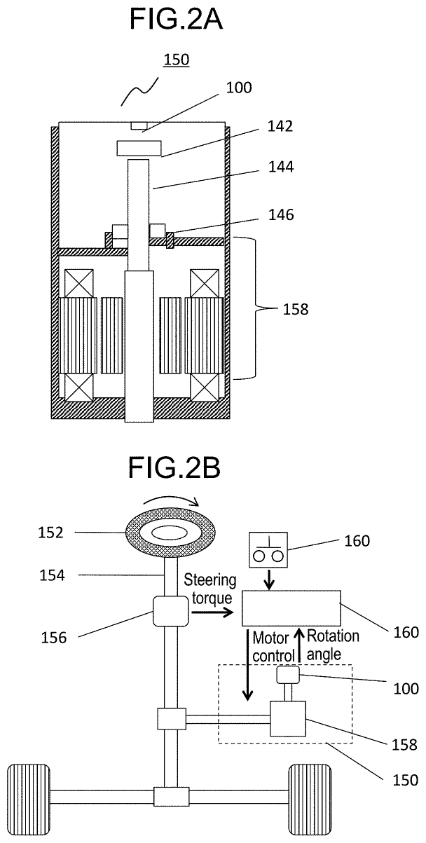

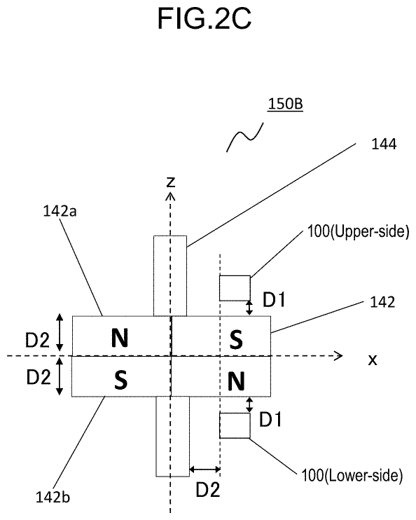

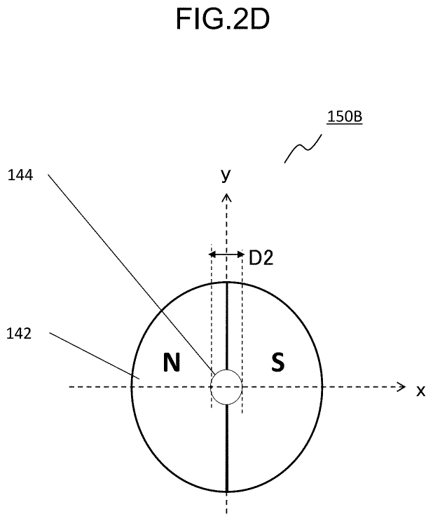

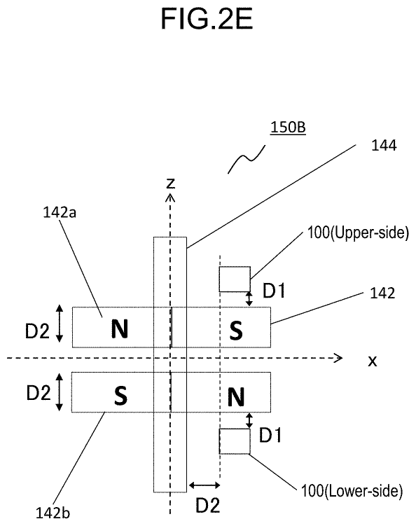

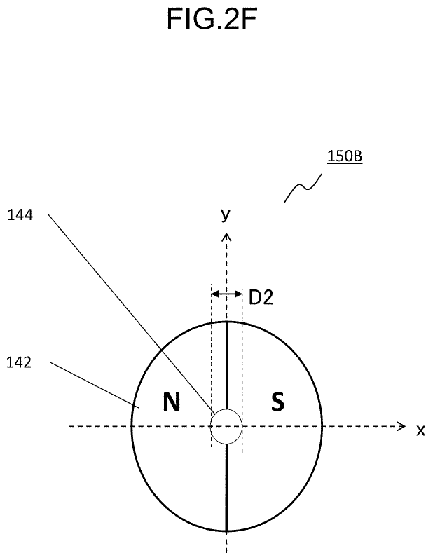

FIG. 2A is a schematic diagram illustrating rotation detection device 150 (first rotation detection device) using magnetic sensor 100.

Rotation detection device 150 includes magnetic sensor 100, detection target magnet 142, rotary shaft 144 that supports detection target magnet 142, bearing 146 that supports rotary shaft 144, and motor 158 that rotates rotary shaft 144.

### (Control System)

FIG. 2B is a schematic diagram illustrating an example of a control system using rotation detection device 150 illustrated in FIG. 2A.

The control system includes steering wheel 152, steering torque 154, torque sensor 156, motor 158, magnetic sensor 100, and electronic control unit (ECU) 160. When a driver rotates steering wheel 152 to change a direction of an automobile, steering torque 154 coupled to steering wheel 152 rotates in a direction identical to the rotation of steering wheel 152. Torque sensor 156 detects relative rotation displacement of an input shaft and an output shaft according to the rotation of steering wheel 152, and transmits an electrical signal to ECU 160. Motor 158 is a motor for assisting steering wheel 152 and steering torque 154, and assists the driver to readily change the direction of the automobile. Magnetic sensor 100 is attached to motor 158, and detects the rotation angle of the motor to control the motor.

### (Second Rotation Detection Device)

FIGS. 2C and 2D are schematic diagrams illustrating rotation detection device 150B (second rotation detection device) that uses magnetic sensor 100 and is different from FIG. 2A. A Z axis in FIG. 2C coincides with a direction extending along rotary shaft 144. An X axis and a Y axis are perpendicular to the Z axis, and pass through a center of detection target magnet 142. FIG. 2C is a schematic diagram viewed from a Y-axis direction, and FIG. 2D is a schematic diagram viewed from a Z-axis direction.

Rotation detection device 150b includes magnetic sensor 100, detection target magnet 142, rotary shaft 144 that supports detection target magnet 142, upper magnetic sensor 100, and lower magnetic sensor 100. Note that wording “upper” can be described as a “positive side of rotary shaft 144 (the Z axis in FIG. 2C)” Wording “lower” may be denoted as a “negative side of rotary shaft 144 (the Z axis in FIG. 2C)”. A width (a width along the X axis in FIG. 2C) of rotary shaft 144 is denoted as D1.

Detection target magnet 142 includes first surface 142a that is supported by rotary shaft 144 (the Z axis in FIG. 2C) and is perpendicular to rotary shaft 144, and second surface 142b facing first surface 142a. A width in a direction along rotary shaft 144 (the Z axis in FIG. 2C) of detection target magnet 142 is denoted as D2 (double D2). Aside of first surface 142a of detection target magnet 142 is an S pole. A side of second surface 142b of detection target magnet 142 is an N pole. In other words, it can be described that “in detection target magnet 142, a surface facing upper magnetic sensor 100 and a surface facing lower magnetic sensor 100 have reversed polarities”. Detection target magnet 142 has reversed polarities on a positive side of the X axis and on a negative side of the X axis.

Upper magnetic sensor 100 is disposed at first gap (D1) from first surface 142a. Upper magnetic sensor 100 is disposed at second gap (D2) from rotary shaft 144. In other words, a distance between upper magnetic sensor 100 and rotary shaft 144 is equal to the width of rotary shaft 144.

Lower magnetic sensor 100 is disposed at first gap (D1) from second surface 142b. Lower magnetic sensor 100 is disposed at second gap (D2) from rotary shaft 144. In other words, a distance between lower magnetic sensor 100 and rotary shaft 144 is equal to the width of rotary shaft 144.

That is, the distance between upper magnetic sensor 100 and rotary shaft 144 is equal to the distance between lower magnetic sensor 100 and rotary shaft 144. Further, the distance between upper magnetic sensor 100 and detection target magnet 142 is equal to the distance between lower magnetic sensor 100 and detection target magnet 142. In addition, first gap (D1) is smaller than second gap (D2). For example, first gap (D1) is 1 mm and second gap (D2) is 5 mm.

In some cases, a noise magnetic field may be applied other than the magnetic field generated by detection target magnet 142 (i.e., the rotation magnetic field to be detected). An example of the noise magnetic field is a leakage magnetic field from the motor. When the noise magnetic field is applied to the magnetic sensor in this manner, the magnetic sensor detects a composite magnetic field of the rotation magnetic field and the noise magnetic field. Hence, when a direction of a magnetic field to be detected and a direction of the noise magnetic field are different from each other, an error is produced in the detection angle of the magnetic sensor.

Herein, in rotation detection device 150B, noise components included in output signals of upper magnetic sensor 100 and lower magnetic sensor 100 have reversed signs, that is, the positive sign and the negative sign. Therefore, calculation of a difference between the outputs of upper magnetic sensor 100 and lower magnetic sensor 100 can cancel a noise component caused by the noise magnetic field.

### (Detection Target Magnet)

Note that in rotation detection device 150 or rotation detection device 150B, detection target magnet 142 may be divided into two pieces as illustrated in FIG. 2E and FIG. 2F. That is, although the sentence “the side of first surface 142a of detection target magnet 142 is the S pole, and the side of second surface 142b of detection target magnet 142 is the N pole” has been described, detection target magnet 142 in this sentence also includes the configuration illustrated in FIG. 2E and FIG. 2F. Note that the Z axis in the drawings coincides with a direction along which rotary shaft 144 extends. The X axis and the Y axis are perpendicular to the Z axis, and pass through the center of detection target magnet 142. FIG. 2E is a schematic diagram viewed from the Y-axis direction, and FIG. 2F is a schematic diagram viewed from the Z-axis direction.

### (Operation of Magnetic Sensor)

### (First Operation, During Ignition-on)

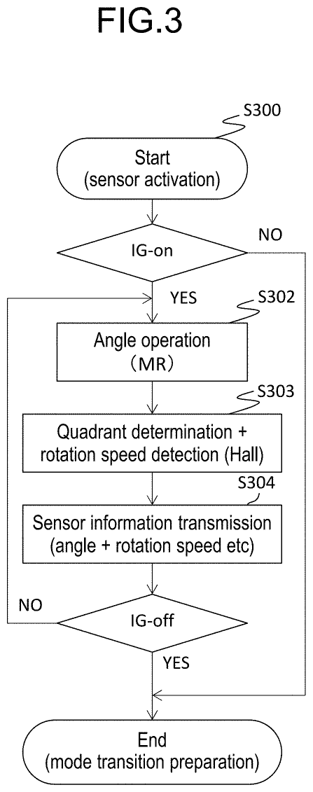

FIG. 3 is an explanatory view of an operation (first operation) of magnetic sensor 100 included in magnetic sensor 100 according to the present exemplary embodiment. FIG. 3 is a flowchart for explaining an operation to detect movement of steering by magnetic sensor 100 during ignition-on (hereinafter, denoted as “IGon” in some cases).

First, after magnetic sensor 100 is activated (S300), magnetic sensor 100 starts detection of the rotation angle (S302 and S303). Each magnetic resistance element of magnetic sensor 100 performs a rotation angle detection operation (S302). Magnetic sensor 100 performs two kinds of detection that are quadrant determination and rotation speed detection based on the output of each Hall element (S303). The rotation angle and the rotation speed obtained through the above operations (operations in S302 and S303) and other signals are transmitted from magnetic sensor 100 to an external microcomputer, for example.

### (Second Operation, During Ignition-Off)

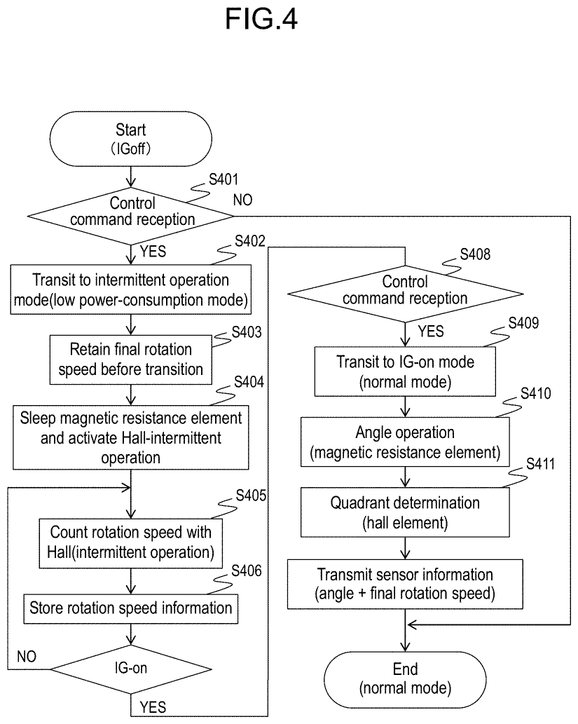

FIG. 4 is an explanatory view of another operation (second operation) of magnetic sensor 100 according to the present exemplary embodiment. FIG. 4 is a flowchart for explaining the operation to detect movement of the steering by magnetic sensor 100 during ignition-off (hereinafter, denoted as “IGoff” in some cases).

First, when IGoff is made, a control command signal is input to magnetic sensor 100 from a control system provided on a vehicle body side (e.g., a steering system) (S401). Then, when receiving this control command signal, magnetic sensor 100 transits to an intermittent operation mode (that is, a low power-consumption mode) (S402). When transiting to the intermittent operation mode, magnetic sensor 100 retains a normal rotation speed (that is, a final rotation speed before transiting to the intermittent operation mode) (S403). At the same time, magnetic sensor 100 causes components of detection circuit 10 used for magnetic resistance element 12 and processing of signals from magnetic resistance element 12 (e.g., the first to fourth amplifiers, offset adjustment circuit 15, gain adjustment circuit 17, and the first and second AD converters) to sleep (that is, stop energization) (S404). Magnetic sensor 100 detects only a rotation speed of a detection target member using the output signal of each Hall element at each certain time (S405). Magnetic sensor 100 retains the rotation speed detected during the intermittent operation mode in memory 80c (S406). When IGon is made, the control command signal is input to magnetic sensor 100 from the control system provided on the vehicle body side (e.g., the steering system) (S408). Magnetic sensor 100 then transits to the normal mode when receiving this control command signal (S409). Upon transition to the normal mode, magnetic sensor 100 detects, only once, a current angle of the detection target member using the signals of each magnetic resistance element and each Hall element (S410, S411). Magnetic sensor 100 then simultaneously transmits this detection result and the rotation speed upon start of the intermittent operation mode (that is, the final rotation speed before transiting to the intermittent operation mode) to the external microcomputer, for example. Note that “simultaneously” mentioned herein is not construed by being limited to a meaning in which two signals are output at the completely same time, and includes a case in which two signals are output at the substantially same time.

Note that, in the intermittent operation mode, the second clock signal generated by second oscillator 80b is used for various kinds of operations (processes) of detection circuit 10. The frequency of the second oscillator is determined according to a period of the intermittent operation. This achieves high efficiency in, for example, power consumption, and mutual monitoring (diagnosis) of two oscillators thus used.

### (Third Operation, During Ignition-Off)

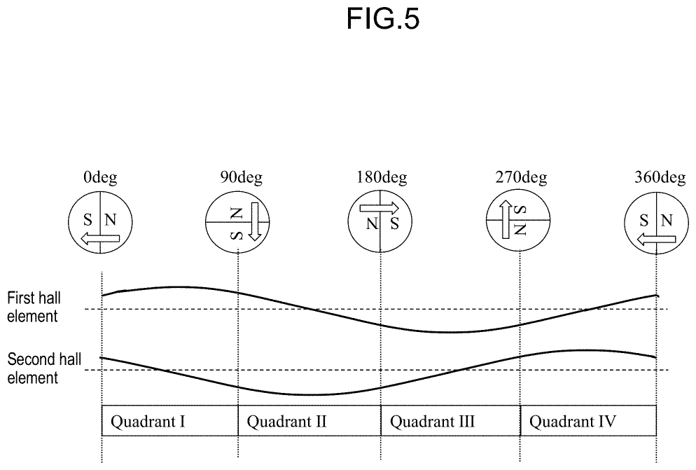

FIG. 5 is an explanatory view of still another operation (third operation) of detection circuit 10 included in the magnetic sensor according to the present exemplary embodiment. FIG. 5 is a waveform chart for explaining the operation to detect the movement of the steering by each Hall element of magnetic sensor 100 during ignition-off.

First, with general magnetic resistance elements, signals including waveforms of Sin 20 and Cos 20 are obtained with respect to rotation angle θ of a detection target member. Hence, the magnetic sensor having only the magnetic resistance element cannot detect up to 180 degrees (with such a magnetic sensor, for example, 90 degrees and 270 degrees are the same signals with each other, and therefore cannot be discriminated from each other).

On the other hand, with general Hall elements, signals including waveforms of Sin 0 and Cos 0 are obtained with respect to rotation angle θ of the detection target member, as illustrated in FIG. 5. Hence, the magnetic sensor having the Hall elements can detect up to 360 degrees.

Magnetic sensor 100 according to the present exemplary embodiment detects the rotation angle of the detection target member with a range of 360 degrees by using the magnetic resistance elements and the Hall elements together.

### (Method for Detecting Rotation)

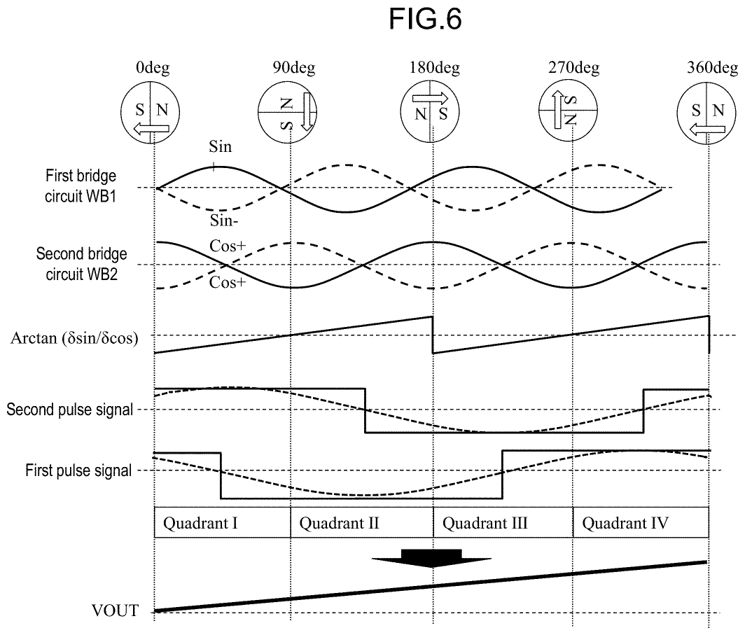

FIG. 6 is an explanatory view of a method for detecting rotation by magnetic sensor 100 according to the present exemplary embodiment. FIG. 6 is a waveform chart for explaining the operation to detect the movement of the steering by each magnetic resistance element of detection circuit 10 during ignition-off.

First, the first pulse signal and the second pulse signal that are signals obtained by converting signals from the Hall elements into pulse signals are generated, like an A-phase output and a B-phase output of an encoder.

Since the first pulse signal and the second pulse signal are used for the quadrant determination, those signals are designed to generate a signal having 1 (Pulse/Revolution) and 4 (Counts/Revolution). Specifically, when the first pulse signal rises or falls, a state of the second pulse signal is checked and counted. A calculation example of the rotation speed will be described below.

When a transition is made from a state of the second pulse signal being 0 when the first pulse signal rises, through a state of the second pulse signal being High when the first pulse signal falls, to a state of the second pulse signal being 0 when the first pulse signal rises, “+one rotation of normal rotation” is detected.

When a transition is made from a state of the second pulse signal being High when the first pulse signal rises, through a state of the second pulse signal being 0 when the first pulse signal falls, to a state of the second pulse signal being High when the first pulse signal rises, “+one rotation of reversed rotation” is detected.

With this configuration, in a case where the rotation angle of the motor moved during IGoff is detected, the detection can be performed with high accuracy and low power when IGon is made again, in comparison with a conventional example.

### (Fourth Operation)

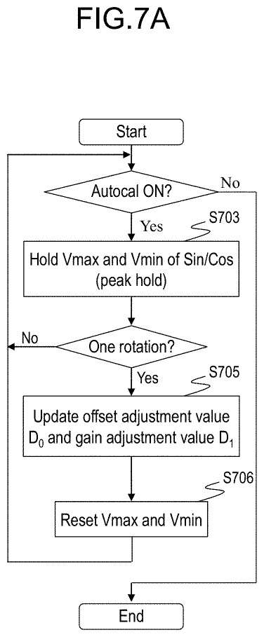

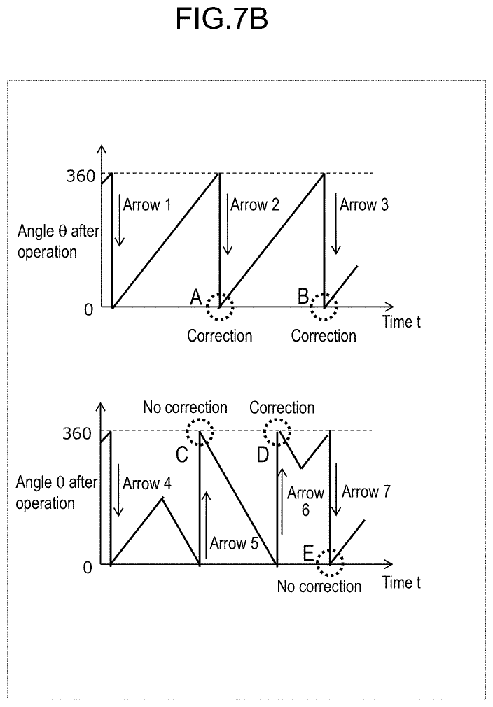

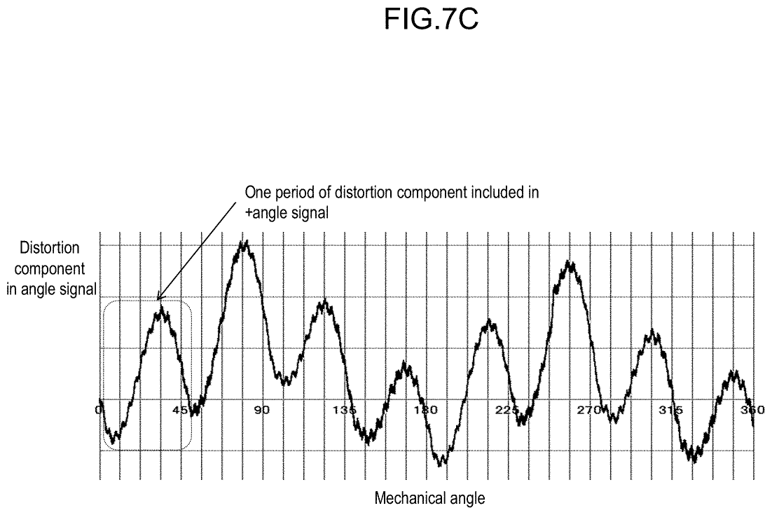

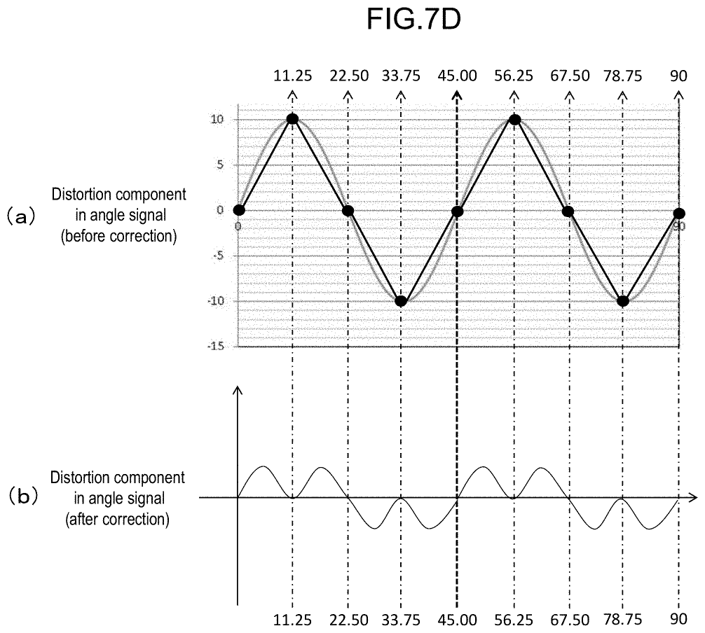

FIGS. 7A and 7B are explanatory views of still another operation (fourth operation) of detection circuit 10 included in magnetic sensor 100 according to the present exemplary embodiment. FIG. 7A is an explanatory view of an operation of detection circuit 10 to correct an output from magnetic resistance element 12, and is a flowchart explaining an operation of automatic correction circuit 70e. FIG. 7B is a conceptual diagram explaining the correction operation.

Incidentally, operational circuit 70 of magnetic sensor 100 includes an “automatic calibration mode (a first correction mode or an active correction mode)” and a “temperature characteristic correction mode (a second correction mode or a passive correction mode)”, for correcting the sin signal and the cos signal output from magnetic resistance element 12.

First, the “temperature characteristic correction mode (the second correction mode or the passive correction mode)” will be described below.

Memory 80c has stored coefficients when dependency of the offset on the temperature is approximated with a polynomial function, for each of the sin signal and the cos signal output from magnetic resistance element 12. In addition, memory 80c has stored coefficients when dependency of the gain (i.e., amplitude) on the temperature is approximated with a polynomial function, for each of the sin signal and the cos signal after A/D conversion.

Offset temperature characteristic correction circuit 70c performs arithmetic processing using temperature information (digital signal) input from temperature sensor 80d and the coefficients related to the dependency of the offset on the temperature, which have been stored in memory 80c, thereby correcting the temperature characteristics of the offsets of the sin signal and the cos signal.

Gain temperature characteristic correction circuit 70d performs arithmetic processing using the temperature information (digital signal) input from temperature sensor 80d and the coefficients related to the dependency of the gain on the temperature, which have been stored in memory 80c, thereby correcting the temperature characteristics of the gains of the sin signal and the cos signal.

Next, the “automatic calibration mode (the first correction mode or the active correction mode)” will be described below.

Automatic correction circuit 70e generates and updates correction values used for correcting the offsets and the gains of the sin signal and the cos signal from magnetic resistance element 12 each time when the detection target member performs one rotation. The updated correction values are used to cause each of the sin signal and the cos signal from magnetic resistance element 12 to always have a constant middle point and constant amplitude. Such an operation that generates and updates the correction values based on the signal from magnetic resistance element 12 obtained during one rotation of the detection target member, and corrects the signal from magnetic resistance element 12 obtained during one subsequent rotation of the detection target member is an operation of the “automatic calibration”.

When the automatic calibration is ON, maximum value Vmax and minimum value Vmin of each of the sin signal and the cos signal from magnetic resistance element 12 are always held (peak holding in S703). When the rotation target member performs one rotation, (Vmax+Vmin)/2 is calculated for the offset and (Vmax−Vmin) is calculated for the gain to generate the correction values that correct the offset and the gain, which are used to update (S705). At the same time, values of Vmax and Vmin are reset to be 0 (S706).

Until one subsequent rotation is completed, the sin signal and the cos signal are corrected based on those updated values of the offset and the gain.

The values of Vmax and Vmin are continuously held again until one subsequent rotation is completed, and the same operation is repeated thereafter.

Note that determination of whether “one rotation” is made is performed when an angle output value after the arctan operation jumps from 360 degrees to 0 degrees (normal rotation), or jumps from 0 degrees to 360 degrees (reversed rotation). However, when a direction representing the normal rotation or the reversed rotation is different from a previous direction, the “one rotation” is not determined, and updating the correction values is not performed in such a case. A more specific description will be made as follows.

The following description is made with reference to FIG. 7B. At time A, when previous rotation is the normal rotation (arrow 1 in FIG. 7B) and current rotation is the normal rotation (arrow 2 in FIG. 7B), the “one rotation” is determined, and automatic correction circuit 70e updates the correction values.

Also at time B, when the previous rotation is the normal rotation (arrow 2 in FIG. 7B) and the current rotation is the normal rotation (arrow 3 in FIG. 7B), the “one rotation” is determined, and automatic correction circuit 70e updates the correction values.

Similarly, when the previous rotation is the reversed rotation and the current rotation is the reversed rotation, the “one rotation” is determined, and automatic correction circuit 70e updates the correction values.

At time C, when the previous rotation is the normal rotation (arrow 4 in FIG. 7B) and the current rotation is the reversed rotation (arrow 5 in FIG. 7B), the “one rotation” is not determined, and automatic correction circuit 70e does not update the correction values.

Note that it has been described that automatic correction circuit 70e does not update the correction values, but automatic correction circuit 70e may stop generating the correction values.

At time E, when the previous rotation is the reversed rotation (arrow 6 in FIG. 7B) and the current rotation is the normal rotation (arrow 7 in FIG. 7B), the “one rotation” is not determined, and automatic correction circuit 70e does not update the correction values.

With this configuration, even when temporal changes in the offsets and the gains (amplitude) of the sin signal and the cos signal of the magnetic sensor element occur, an adjusted value is updated as appropriate, whereby the offsets and the gains (amplitude) can always be kept constant. In addition, even when the detection target member performs both the normal rotation and the reversed rotation, the offsets can accurately be updated.

Note that, the operation is preferably performed such that when the “automatic calibration mode (the first correction mode or the active correction mode)” is ON, the “temperature characteristic correction mode (the second correction mode or the passive correction mode)” is OFF, and when the “automatic calibration mode (the first correction mode or the active correction mode)” is OFF, the “temperature characteristic correction mode (the second correction mode or the passive correction mode)” is ON. In other words, magnetic sensor 100 switches between the “automatic calibration mode (the first correction mode or the active correction mode)” and the “temperature characteristic correction mode (the second correction mode or the passive correction mode)”. With this configuration, when the automatic calibration mode is ON, all temporal changes including the temperature characteristic can be corrected, whereby the temperature characteristic correction mode can be set to be OFF. On the other hand, in the automatic calibration mode, since the correction values are not updated until the rotation target member performs one rotation, the passive correction mode is used more desirably than the automatic calibration mode in an application in which the rotation target does not perform one rotation or an application in which the offsets and the gains largely vary in value during the one rotation.

Note that, in the description of the automatic calibration mode, a case where both the offsets and the gains are corrected has been described, but the present disclosure is not limited to this case. That is, a mode for correcting only the offsets or the gains may be provided.

Note that, in the description of the automatic calibration mode and the temperature characteristic correction mode, a case where the sin signal and the cos signal of the magnetic resistance element from the magnetic resistance element are corrected has been described, but the present disclosure is not limited to this case. An element other than a magnetic resister may be used, as long as the element outputs a sin signal and a cos signal according to rotation of the detection target member, and reacts to magnetism. In other words, the automatic calibration mode and the temperature characteristic correction mode can be used to correct the sin signal and the cos signal of a magnetic element.

Note that the operation of automatic correction circuit 70e in the automatic calibration mode can be described in another way. Specifically, the description can be made as follows. When the angle signal output from angle detection circuit 70a changes from 360 degrees to 0 degrees is defined as the normal rotation, and when the angle signal output from angle detection circuit 70a changes from 0 degrees to 360 degrees is defined as the reversed rotation, automatic correction circuit 70e generates and/or updates the correction values when the change is made from the normal rotation to the normal rotation or from the reversed rotation to the reversed rotation.

Note that the operation of automatic correction circuit 70e in the automatic calibration mode can be described in still another way. Specifically, the description can be made as follows.

The automatic calibration mode is a correction method of the rotation detection device that includes a first step that generates and updates the correction values from the differential signal between the sin signal and the cos signal, a second step that detects whether the detection target member rotates in order “from the normal rotation to the reversed rotation” or “from the reversed rotation to the normal rotation”, and a third step that stops the first step when the detection target member is detected to rotate in order “from the normal rotation to the reversed rotation” or “from the reversed rotation to the normal rotation” in the second step.

Automatic correction circuit 70e can have still another correction mode (hereinafter, this correction mode can be described as an 11.25 correction mode).

FIG. 7C is a waveform chart illustrating an output of the magnetic sensor. Specifically, FIG. 7C illustrates a distortion component of the angle signal (that can be denoted as a third signal) representing a rotation angle after angle detection circuit 70a performs the arctan operation. In FIG. 7C, a horizontal axis is a mechanical angle, and a vertical angle is the distortion component included in the angle signal representing the rotation angle after angle detection circuit 70a performs the arctan operation. As seen from FIG. 7C, the inventors have found that the distortion component (or can be described as, for example, a “distortion waveform” or a “distortion signal”) of the angle signal has a period of about 45 degrees.

FIG. 7D is a view explaining an operation of automatic correction circuit 70e in the 11.25 correction mode. Part (a) of FIG. 7D is a waveform chart before the correction, and part (b) of FIG. 7D is a waveform chart after the correction. Black points in part (a) of FIG. 7D indicate positions for correcting the distortion component.

As indicated in part (a) of FIG. 7D, the 11.25 correction mode corrects the distortion component for each section of 11.25 degrees. As described above, since the distortion component has the period of about 45 degrees, correction for each section of 11.25 degrees can correct the distortion component with high accuracy, as indicated in part (b) of FIG. 7D.

Note that “correction for each section of 11.25 degrees” can be expressed as “correction for each 32 sections (360 deg/11.25 deg=32 sections)”. Alternatively, multiples of 32 sections (such as 64 sections, 96 sections, and 128 sections) can be applied as sections for correction. The 11.25 correction mode can also be expressed such that “when n is a natural number, a signal (e.g., +sin signal) output from magnetic resistance element 12 is corrected for each section in a ( 1/32n) period of the signal”.

Note that the correction can be performed by connecting adjacent peaks in the distortion waveform. Note that automatic correction circuit 70e in this case preferably operates to perform correction for each section of 22.50 degrees (correction for each 16 sections (360 deg/22.50 deg=16 sections)). Alternatively, multiples of 16 sections (such as 32 sections and 48 sections) may be applied as the sections for correction.

As a summary, the operation of automatic correction circuit 70e can be described as follows. Automatic correction circuit 70e corrects the angle signal for each section in a ( 1/16n) period of the period of the angle signal, when n is a natural number.

### Second Exemplary Embodiment

### (Magnetic Sensor)

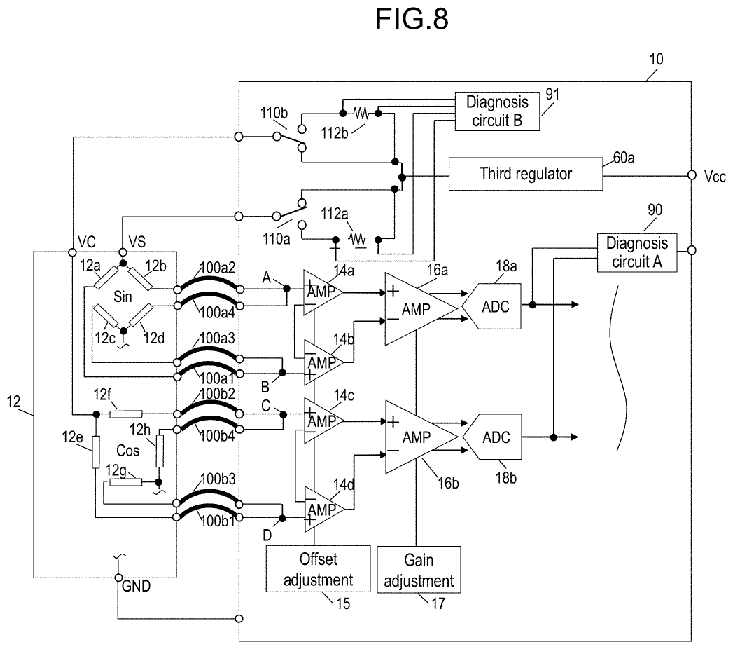

FIG. 8 is a block diagram illustrating a magnetic sensor according to a second exemplary embodiment. The magnetic sensor illustrated in FIG. 8 will be described below.

An end of first sine magnetic resistance element 12a and an end of second sine magnetic resistance element 12b are connected to potential Vs.

An end of third sine magnetic resistance element 12c and an end of fourth sine magnetic resistance element 12d are connected to ground (GND in FIG. 8).

The other end of first sine magnetic resistance element 12a is connected to detection circuit 10 through wire 100al.

The other end of second sine magnetic resistance element 12b is connected to detection circuit 10 through wire 100a2.

The other end of third sine magnetic resistance element 12c is connected to detection circuit 10 through wire 100a3.

The other end of fourth sine magnetic resistance element 12d is connected to detection circuit 10 through wire 100a4.

In other words, the other ends of first to fourth sine magnetic resistance elements are connected to detection circuit 10 through wires 100al to 100a4, respectively.

Inside detection circuit 10, connection point A of the other end of first sine magnetic resistance element 12a and the other end of third sine magnetic resistance element 12c (i.e., middle point A configuring first bridge circuit WB1) is formed.

A signal at connection point A (middle point A) is input into first amplifier 14a to be amplified, and is then input into first differential amplifier 16a.

Inside detection circuit 10, connection point B of the other end of second sine magnetic resistance element 12b and the other end of fourth sine magnetic resistance element 12d (i.e., middle point B configuring first bridge circuit WB1) is formed.

A signal at connection point B (middle point B) is input into second amplifier 14b to be amplified, and is then input into first differential amplifier 16a.

The other end of first cosine magnetic resistance element 12e is connected to detection circuit 10 through wire 100b1.

The other end of second cosine magnetic resistance element 12f is connected to detection circuit 10 through wire 100b2.

The other end of third cosine magnetic resistance element 12g is connected to detection circuit 10 through wire 100b3.

The other end of fourth cosine magnetic resistance element 12h is connected to detection circuit 10 through wire 100b4.

In other words, the other ends of first to fourth cosine magnetic resistance elements are connected to detection circuit 10 through wires 100b1 to 100b4, respectively.

Note that the wires are metal wires (for wire bonding), for example.

Inside detection circuit 10, connection point C of the other end of first cosine magnetic resistance element 12e and the other end of third cosine magnetic resistance element 12g (i.e., middle point C configuring second bridge circuit WB2) is formed.

A signal at connection point C (middle point C) is input into third amplifier 14c to be amplified, and is then input into second differential amplifier 16b.

Inside detection circuit 10, connection point D of the other end of second cosine magnetic resistance element 12f and the other end of fourth cosine magnetic resistance element 12h (i.e., middle point D configuring second bridge circuit WB2) is formed.

A signal at connection point D (middle point D) is input into fourth amplifier 14d to be amplified, and is then input into second differential amplifier 16b.

Note that second bridge circuit WB2 and the signal from second bridge circuit WB2 can be described as a second magnetic resistance element and a second detection signal, respectively.

Disconnection detection of wires 100al to 100a4 and 100b1 to 100b4 that connect magnetic resistance element 12 and detection circuit 10 will be described below.

In a normal operation, each pieces of potential of grounding points A, B, C, and D that are input signals from magnetic resistance element 12 is around midpoint potential, and as a result, first amplifier 14a to fourth amplifier 14d, first differential amplifier 16a, and first AD converter 18a output values around the midpoint potential. On the other hand, when any one of wires 100al to 100a4 and 100b1 to 100b4 is cut, a grounding point of a cutting portion of magnetic resistance element 12 is fixed to High (VS or VC) or Low (GND). Therefore outputs of first amplifier 14a to fourth amplifier 14d, first differential amplifier 16a, second differential amplifier 16b, and first AD converter 18a, 18b are fixed to High or Low. As a result, diagnosis circuit A90 detects that the output of first AD converter 18a or second AD converter 18b deviates from a normal operation range, and therefore diagnoses as abnormality determination, to output an abnormality signal. With this configuration, disconnection of the connecting parts that connect magnetic resistance element 12 and detection circuit 10 can be detected.

Note that a case where, by detecting that the output of first AD converter 18a or second AD converter 18b is deviated from the normal operation range (that can be described as a predetermined range or a predetermined voltage range, for example, in other words), the abnormality determination is diagnosed, and then the abnormality signal is output has been described, but the present disclosure is not limited to this case. For example, by detecting that the output of first differential amplifier 16a or the second differential amplifier deviates from a normal operation range, the abnormality determination may be diagnosed, and then the abnormality signal may be output.

Note that the configuration in FIG. 8 can differently be described as follows. The configuration includes a first board including the bridge circuit (wb1 or wb2) configured with the first to fourth magnetic resistance elements (first to fourth sine magnetic resistance elements or the first to fourth cosine magnetic resistance elements), a second board including detection circuit 10 connected to the first to fourth magnetic resistance elements, and the first, second, third, fourth wires (100a1 to 100a4 or 100b1 to 100b4) that connect the ends of the first, second, third, fourth magnetic resistance elements and detection circuit 10. Herein, the middle points of the bridge circuit are disposed in the second board.

Next, abnormality detection of a resistance value of magnetic resistance element 12 will be described below.

Magnetic resistance element 12 is connected to third regulator 60a inside detection circuit 10, through current detection resisters 112a, 112b, or with direct connection (without resisters), which is switched by changeover switches 110a, 110b. In the normal operation, changeover switches 110a, 110b select current paths that are directly connected to third regulator 60a. Only when the resistance value of magnetic resistance element 12 is diagnosed, changeover switches 110a, 110b select current paths that are connected to third regulator 60a through resisters 112a, 112b. Herein, diagnosis circuit B91 is connected to third regulator 60a, and measures voltages between both terminals of resisters 112a, 112b. Alternatively, a value of a current flowing through each resister is measured. In this case, when a resistance value of magnetic resistance element 12 is abnormal due to any fault, or when any wire of VS and VC is disconnected, amounts of currents flowing through resisters 112a, 112b deviate from a normal range. Diagnosis circuit B91 determines that abnormality occurs based on this deviation from the normal range, and outputs the abnormality signal. This configuration enables detection of abnormality in resistance value of magnetic resistance element 12 and disconnection of any of the wires of VS, VC. Also when sheet resistance of magnetic resistance element 12 varies (i.e., resistance values of four magnetic resistance elements configuring the bridge circuit simultaneously vary), the failure can be detected.

Note that, after a period in which the current path connected to third regulator 60a through resister 112a is selected (i.e., a period for diagnosing first bridge circuit wb1), a period in which the current path connected to third regulator 60a through resister 112b is selected (i.e., a period for diagnosing second bridge circuit wb) is preferably provided. With this configuration, diagnosis circuit B91 sequentially receives the value of the current flowing through first bridge circuit wb1 and the value of the current flowing through second bridge circuit wb2. Therefore, first bridge circuit wb1 and second bridge circuit wb2 can be diagnosed without increasing a circuit scale of diagnosis circuit B91.

Note that changeover switch 110a, changeover switch 110b, resister 112a, and resister 112b may be described as a first switch, a second switch, a first resister, and a second resister, respectively. Furthermore, an electrical path reaching magnetic resistance element 12 without passing through first resister 112a, an electrical path reaching magnetic resistance element 12 while passing through first resister 112a, an electrical path reaching magnetic resistance element 12 without passing through second resister 112b, and an electrical path reaching magnetic resistance element 12 while passing through second resister 112b may be described as a first current path, a second current path, a third current path, and a fourth current path, respectively. In addition, diagnosis circuit B91 may be described such that diagnosis circuit B91 is connected to the second current path and the fourth current path. The second current path is larger than the first current path in resister value. It can be said that the fourth current path is larger than the third current path in resister value. Note that the operation of diagnosis circuit B91 can be described in another expression. For example, the description can be made as follows.

A diagnostic method performed by diagnosis circuit B91 is a method including first to sixth steps described below.

In the first step, third regulator 60a supplies potential to first bridge circuit wb1 through the first current path.

In the second step, third regulator 60a supplies potential to first bridge circuit wb1 through the second current path (that is larger than the first current path in resistance).

In the third step, third regulator 60a supplies potential to second bridge circuit wb2 through the third current path.

In the fourth step, third regulator 60a supplies potential to second bridge circuit wb2 through the fourth current path (that is larger than the third current path in resistance).

In the fifth step, an error signal is generated when the current value in the second step is larger or smaller than a predetermined value.

In the sixth step, the error signal is generated when the current value in the fourth step is larger or smaller than a predetermined value.

Note that it is preferable that the second and fifth steps and the fourth and sixth steps are performed not simultaneously but sequentially. With this configuration, diagnosis circuit B91 sequentially receives the value of the current flowing through first bridge circuit wb1 and the value of the current flowing through second bridge circuit wb2. Therefore, first bridge circuit wb1 and second bridge circuit wb2 can be diagnosed without increasing a circuit scale of diagnosis circuit B91.

### (Configuration of Magnetic Sensor)

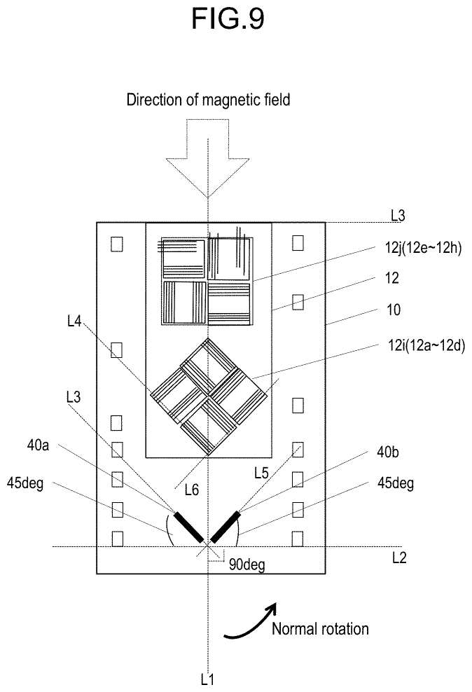

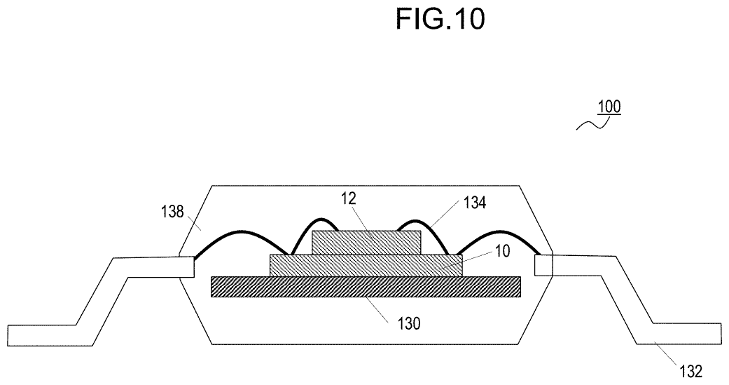

FIG. 9 is a top view of magnetic sensor 100. FIG. 10 is a front view of magnetic sensor 100. In FIG. 9, a part of a configuration is omitted. FIG. 9 illustrates magnetic sensor 100 that uses a vertical Hall element that detects a magnetic field parallel to a circuit board mounting detection circuit 10. Note that in the following description, first sine magnetic resistance elements 12a to 12d are collectively referred to as “first magnetic resistance element group 12i”, and first cosine magnetic resistance elements 12e to 12h are collectively referred to as “second magnetic resistance element group 12j”, in some cases.

Magnetic sensor 100 includes magnetic resistance element 12, detection circuit 10, die pad 130, wires 134, sealing resin 138, and leads 132.

Magnetic resistance element 12 and detection circuit 10 are placed on die pad 130.

Sealing resin 138 seals magnetic resistance element 12, detection circuit 10, and die pad 130.

Leads 132 extend from sealing resin 138 to achieve electrical connection with external devices.

Straight line L1 in FIG. 9 passes through substantial centers of first to fourth sine magnetic resistance elements 12a to 12d and first to fourth cosine magnetic resistance elements 12e to 12h. Herein first Hall element 40a and second Hall element 40b are disposed so as to be line symmetry with respect to straight line L1. More specifically, first Hall element 40a and second Hall element 40b are inclined with respect to straight line L1 at 45 degrees. In other words, straight line L4 passing through a substantial center of straight line L3 passing through a substantial center of first Hall element 40a is parallel to a magnetic resistance pattern included in any of first to fourth sine magnetic resistance elements 12a to 12d. Straight line L5 passing through a substantial center of second Hall element 40b is parallel to a magnetic resistance pattern included in any of first to fourth sine magnetic resistance elements 12a to 12d.

Second Hall element 40b is equal to first Hall element 40a rotated by 90 degrees.

First Hall element 40a and second Hall element 40b are both the vertical Hall element for detecting a magnetic field in a direction parallel to the circuit board mounting detection circuit 10. Therefore first Hall element 40a and second Hall element 40b are preferably disposed near the center of the circuit board, which can easily acquire the magnetic field in the direction parallel to the circuit board.

### (First Modification)

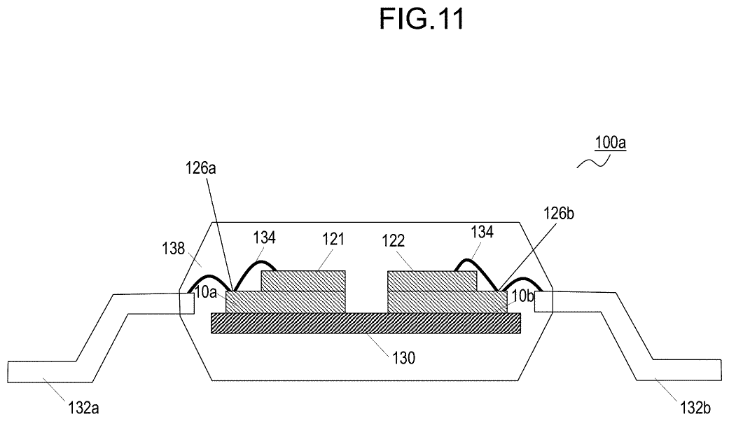

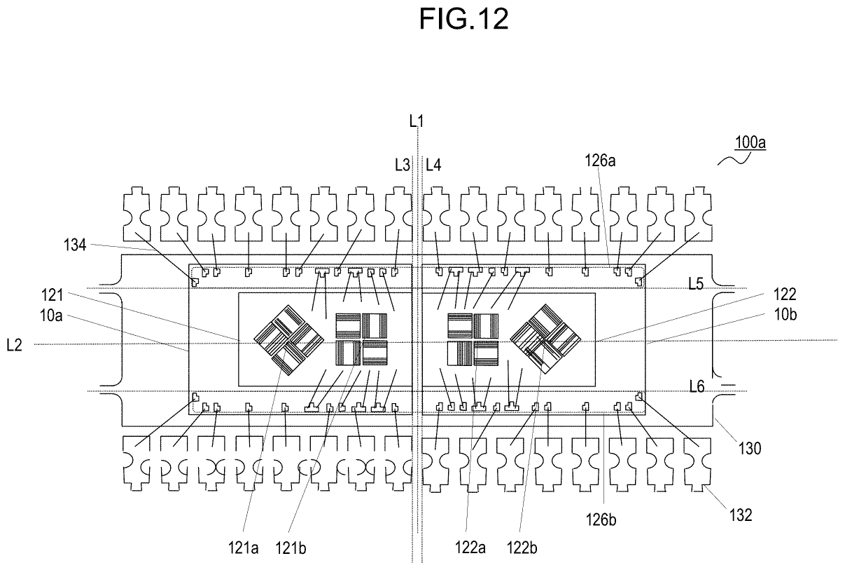

FIG. 11 is a front view of magnetic sensor 100a according to a first modification of the present exemplary embodiment. FIG. 12 is a top view of this magnetic sensor 100a. In FIG. 12, a part of a configuration is omitted. Note that in the following description, first to fourth sine magnetic resistance elements 12a to 12d included in magnetic resistance element 121 are collectively referred to as “first magnetic resistance element group 121a”, and first to fourth cosine magnetic resistance elements 12e to 12h included in magnetic resistance element 121 are collectively referred to as “second magnetic resistance element group 121b”, in some cases. Similarly, first to fourth sine magnetic resistance elements 12a to 12d included in magnetic resistance element 122 are collectively referred to as “first magnetic resistance element group 122a”, and first to fourth cosine magnetic resistance elements 12e to 12h included in magnetic resistance element 122 are collectively referred to as “second magnetic resistance element group 122b”, in some cases. Note that detection circuit 10a and detection circuit 10b may be described as a “first circuit board” and a “second circuit board”, respectively.

Magnetic sensor 100a includes magnetic resistance element 121, magnetic resistance element 122, detection circuit 10a, detection circuit 10b, die pad 130, wires 134, sealing resin 138, leads 132a, and leads 132b.

Magnetic resistance elements 121, 122 and detection circuits 10a, 10b are placed on die pad 130.

Sealing resin 138 seals magnetic resistance elements 121, 122, detection circuits 10a, 10b and die pad 130.

Leads 132a, 132b extend from sealing resin 138 to achieve electrical connection with external devices.

Detection circuit 10a receives a signal from magnetic resistance element 121. A configuration and an operation of detection circuit 10a are the same as the configuration and the operation of detection circuit 10.

Detection circuit 10b receives a signal from magnetic resistance element 122. A configuration and an operation of detection circuit 10b are the same as the configuration and the operation of detection circuit 10.

Magnetic resistance element 121 and magnetic resistance element 122 are disposed so as to be line symmetry with respect to straight line L1 in FIG. 12. Alternatively, a substantial center of first magnetic resistance element group 121a, a substantial center of second magnetic resistance element group 121b, a substantial center of first magnetic resistance element group 122a, and a substantial center of second magnetic resistance element group 122b are on straight line L2. Disposition of magnetic resistance element 121 and magnetic resistance element 122 in this manner can improve redundancy of the sensor, thereby improving reliability.

Further, on a side closer to magnetic sensor 100a, an end surface of magnetic resistance element 121 and an end surface of detection circuit 10a (i.e., of the first circuit board) are disposed to be aligned. In other words, in a top view, the end surface of magnetic resistance element 121 and the end surface of detection circuit 10a (i.e., of the first circuit board) are on straight line L3.

Further, on the side closer to magnetic sensor 100a, an end surface of magnetic resistance element 122 and an end surface of detection circuit 10b (i.e., of the second circuit board) are disposed to be aligned. In other words, in a top view, the end surface of magnetic resistance element 122 and the end surface of detection circuit 10b (i.e., of the second circuit board) are on straight line L4.

Each of detection circuit 10a and detection circuit 10b includes an electrode group electrically connected to the magnetic resistance element and the leads. Here the electrode group includes first electrode group 126a and second electrode group 126b. First electrode group 126a and second electrode group 126b are parallel to straight line L5 and straight line L6, respectively. In this manner, the electrode groups (and wires connected thereto) are spaced away from straight line L5 (i.e., the center of each magnetic resistance element). With this configuration, the magnetic sensor hardly receives interference from the electrode groups (and the wires connected thereto), thereby improving accuracy of the magnetic sensor.

### (Second Modification)

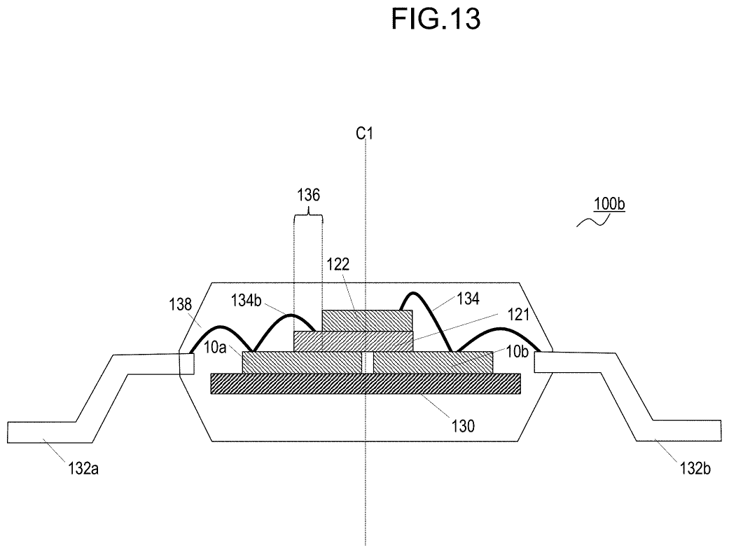

FIG. 13 is a front view of magnetic sensor 100b according to a second modification of the present exemplary embodiment.

Magnetic sensor 100b includes magnetic resistance element 121, magnetic resistance element 122, detection circuit 10a, detection circuit 10b, die pad 130, wires 134, sealing resin 138, leads 132a, and leads 132b.

In magnetic sensor 100b, magnetic resistance element 122 is disposed on magnetic resistance element 121. Here a center of magnetic resistance element 121 and a center of magnetic resistance element 122 are disposed so as to substantially coincide with each other. In other words, the center of magnetic resistance element 121 and the center of magnetic resistance element 122 are on straight line C1. With this configuration, the center of magnetic resistance element 121 and the center of magnetic resistance element 122 are close to each other. Therefore signals obtained from magnetic resistance element 121 and magnetic resistance element 122 are preferably caused to be substantially identical.

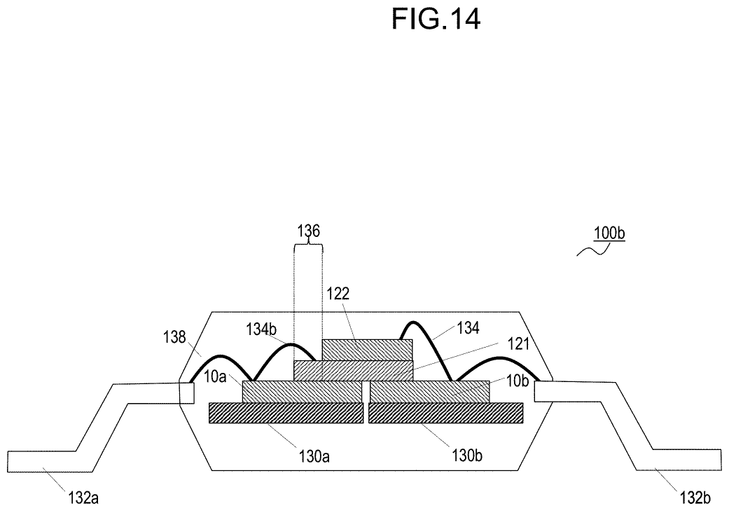

Further, magnetic sensor 100b includes portion 136 that does not overlap magnetic resistance element 122 in a top view, in other words, portion 136 projecting from magnetic resistance element 121. Portion 136 is configured by extending a board configuring magnetic resistance element 121. In other words, a width of the board configuring first magnetic resistance element 121 is larger than a width of a board configuring second magnetic resistance element 122. This portion exceeding the width of the board configuring second magnetic resistance element 122 corresponds to projecting portion 136. Portion 136 is a portion for providing a region for disposition of wires 134b. Portion 136 thus provided can allow the center of magnetic resistance element 121 and the center of magnetic resistance element 122 to substantially coincide with each other. Therefore the signals obtained from magnetic resistance element 121 and magnetic resistance element 122 are preferably caused to be substantially identical. Note that, as illustrated in FIG. 14, the die pad may be divided into die pads 130a, 130b. This configuration with the divided die pads can also be adopted in magnetic sensor 100a in FIG. 11.

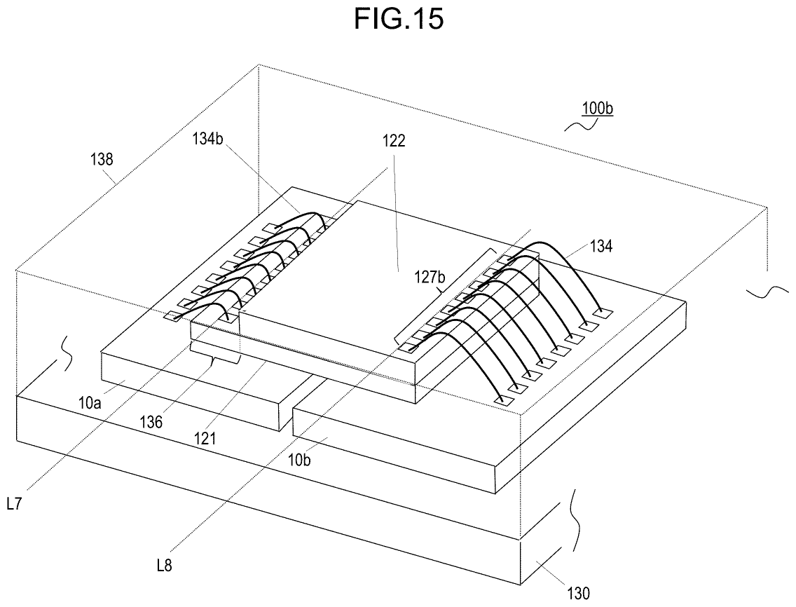

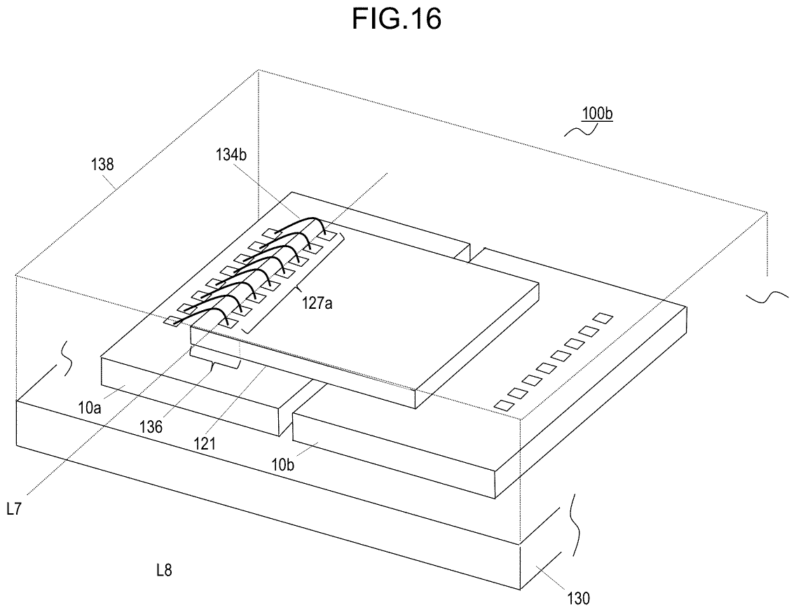

FIG. 15 is a perspective view of magnetic sensor 100b, and FIG. 16 is another perspective view of magnetic sensor 100b. In FIG. 15, a part of a configuration is omitted, or simplified. In FIG. 16, a part of the configuration is omitted from FIG. 15.

First magnetic resistance element 121 includes third electrode group 127a. Second magnetic resistance element 122 includes fourth electrode group 127b.

Third electrode group 127a is disposed at portion 136 projecting from first magnetic resistance element 121. Third electrode group 127a is disposed along straight line L7.

Fourth electrode group 127b is disposed on second magnetic resistance element 122. Fourth electrode group 127b is disposed along straight line L8. Here straight line L7 is parallel to straight line L8.

Note that a case where magnetic sensor 100 is attached to the motor for assisting steering wheel 152 and steering torque 154 has been described, but the present disclosure is not limited to this case. For example, magnetic sensor 100 can be used for detecting a lever position of a shift lever of an automobile. In other words, magnetic sensor 100 can independently be used alone.

Note that diagnosis circuit A90 may be a part of operational circuit 70.

### (Magnetic Resistance Element)

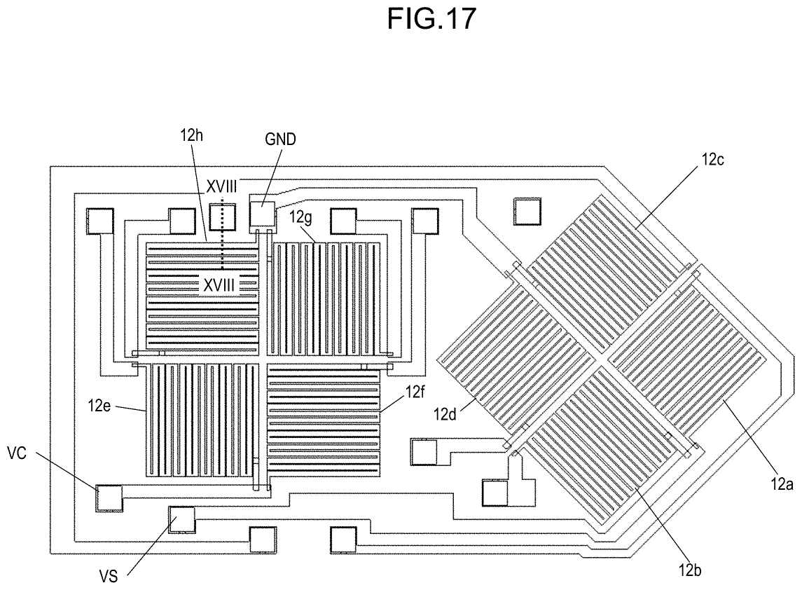

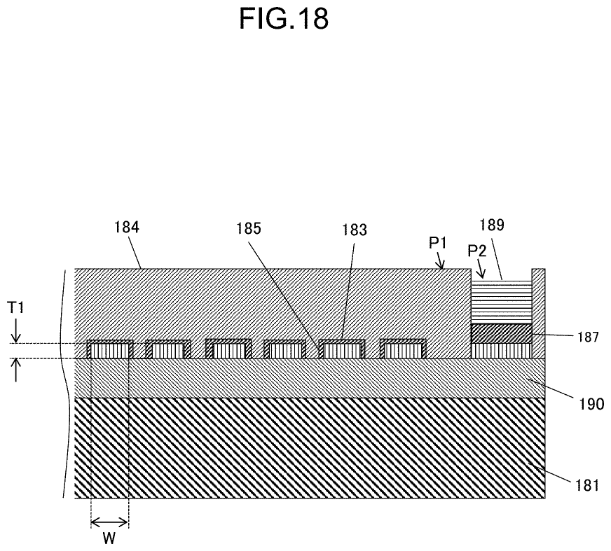

FIG. 17 is a front view of the magnetic resistance element in the magnetic sensor in FIG. 8, and FIG. 18 is a cross-sectional view taken along line XVIII-XVIII in FIG. 17.

First to fourth sine magnetic resistance elements 12a to 12d, first to fourth cosine magnetic resistance elements 12e to 12h, ground terminal (GND), terminals VS, VC are disposed as illustrated in FIG. 17.

In the magnetic resistance element in FIG. 18, silicon dioxide layer 190 is formed on silicon substrate 181, and magneto-resistance (MR) layer 185 and first protective layer 183 are selectively formed on silicon dioxide layer 190. Here in the MR layer, its thickness is T1, and its width is W. Thickness T1 is the same as T1 described in FIG. 10. Second protective layer 184 formed from polycrystal silicon dioxide is formed on MR layer 185 and first protective layer 183. Hole P2 is formed so as to reach silicon dioxide layer 190 by rejecting a part of second protective layer 184, and Ti layer 187 and wiring layer 189 are sequentially formed so as to fill hole P2. A step is formed between surface P1 of second protective layer 184 and hole P2. First protective layer 183 has a function as a coupling layer.

### Third Exemplary Embodiment

### (Magnetic Sensor)

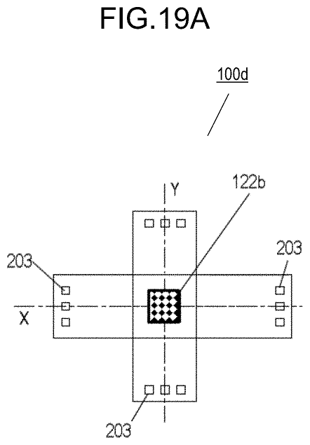

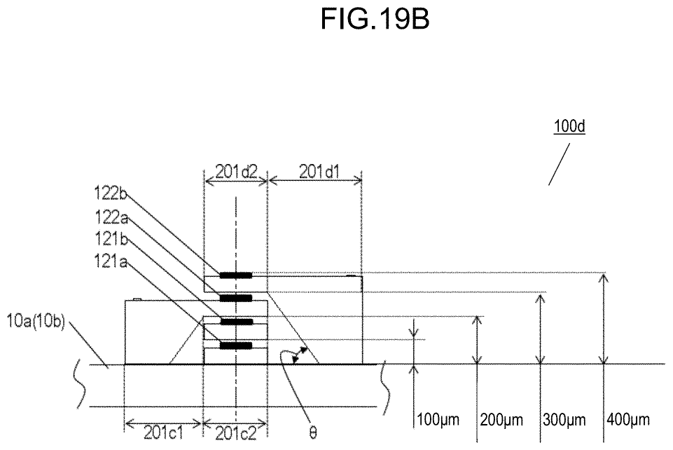

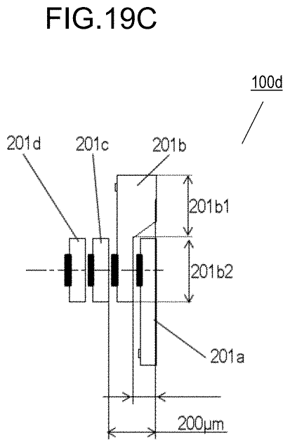

FIGS. 19A to 19C are views illustrating magnetic sensor 100d according to a third exemplary embodiment. FIG. 19A is a top view of magnetic sensor 100d, FIG. 19B is a front view of magnetic sensor 100d, and FIG. 19C is a side view of magnetic sensor 100d.

In FIGS. 19A to 19C, a part of a configuration is omitted, or simplified.

Magnetic sensor 100d includes first magnetic resistance element group 121a, second magnetic resistance element group 122b, detection circuit 10a(10b), first substrate 201a, second substrate 201b, third substrate 201c, and fourth substrate 201d. Note that as already described, first to fourth sine magnetic resistance elements 12a to 12d are collectively referred to as “first magnetic resistance element group 121a (or first magnetic resistance element group 122a)”, and first to fourth cosine magnetic resistance elements 12e to 12h are collectively referred to as “second magnetic resistance element group 121b (or second magnetic resistance element group 122b)”.

First magnetic resistance element group 121a is disposed on first substrate 201a.

Second magnetic resistance element group 121b is disposed on second substrate 201b. Second substrate 201b includes first portion 201b1 thicker than first substrate 201a, and second portion 201b2 extending from this thicker portion to overlap first substrate 201a. Second magnetic resistance element group 121b is disposed on second portion 201b2 thus overlapping.

First magnetic resistance element group 122a is disposed on third substrate 201c. Third substrate 201c includes first portion 201c1 thicker than second substrate 201b, and second portion 201c2 extending from this thicker portion to overlap second substrate 201b. First magnetic resistance element group 122a is disposed on second portion 201c2 thus overlapping.

Second magnetic resistance element group 122b is disposed on fourth substrate 201d. Fourth substrate 201d includes first portion 201dl thicker than fourth substrate 201d, and second portion 201d2 extending from this thicker portion to overlap third substrate 201c. Second magnetic resistance element group 122b is disposed on second portion 201d2 thus overlapping.

First substrate 201a and second substrate 201b are aligned along a Y axis (second axis). Third substrate 201c and fourth substrate 201d are aligned along an X axis (first axis). The X axis and the Y axis are orthogonal to each other. With this configuration, at least a part of each substrate is exposed in a top view, whereby electrodes 203 for electrically connecting each substrate to detection circuit 10a(10b) can be provided. In other words, at least a part of each substrate is being exposed in a top view, whereby electrodes 203 for electrically connecting each substrate to detection circuit 10a(10b) can be provided.

Each of second substrate 201b, third substrate 201c, and fourth substrate 201d is placed on a mount board. In the present exemplary embodiment, the mount board is a circuit board on which detection circuits 10a, 10b are disposed. Each of first portion 201b1 of second substrate 201b, first portion 201c1 of third substrate 201c, and first portion 201d1 of fourth substrate 201d includes a portion inclined with respect to the mount board at predetermined angle θ. Here θ is from 45 degrees to 55 degrees.

Thicknesses of first substrate 201a, second portion 201b2 of second substrate 201b, second portion 201c2 of third substrate 201c, and second portion 201d2 of fourth substrate 201d are substantially identical to one another.

Second portion 201b2 of second substrate 201b, second portion 201c2 of third substrate 201c, and second portion 201d2 of fourth substrate 201d can be formed by partially rejecting a silicon substrate by silicon anisotropic etching using an alkaline anisotropic etching solution of a wet type (e.g., a potassium hydroxide solution (KOH), or a tetramethyl ammonium hydroxide solution (TMAH)).

Centers of first magnetic resistance element group 121a and second magnetic resistance element group 122b substantially coincide with each other in a top view. In other words, at least parts of first magnetic resistance element group 121a and second magnetic resistance element group 122b overlap each other in a top view (at least parts of first magnetic resistance element group 121a and second magnetic resistance element group 122b overlap in a top view). With this configuration, center positions of first magnetic resistance element group 121a and second magnetic resistance element group 121b substantially coincide with each other. Therefore a phase shift between a Sin signal output from first magnetic resistance element group 121a and a COS signal output from second magnetic resistance element group 121b can be reduced. Hence an angular error of magnetic sensor 100d is reduced. Furthermore, a phase shift between angle signals output from first magnetic resistance element group 121a and second magnetic resistance element group 121b and angle signals output from first magnetic resistance element group 122a and second magnetic resistance element group 122b can also be reduced. This improves redundancy of magnetic sensor 100d.

Note that, as described above, the magnetic sensor of the present exemplary embodiment can detect the angle, but the present disclosure is not limited thereto. For example, the magnetic sensor of the present exemplary embodiment can detect linear displacement of an object. This function will be described in detail below.

### (Detection Operation)

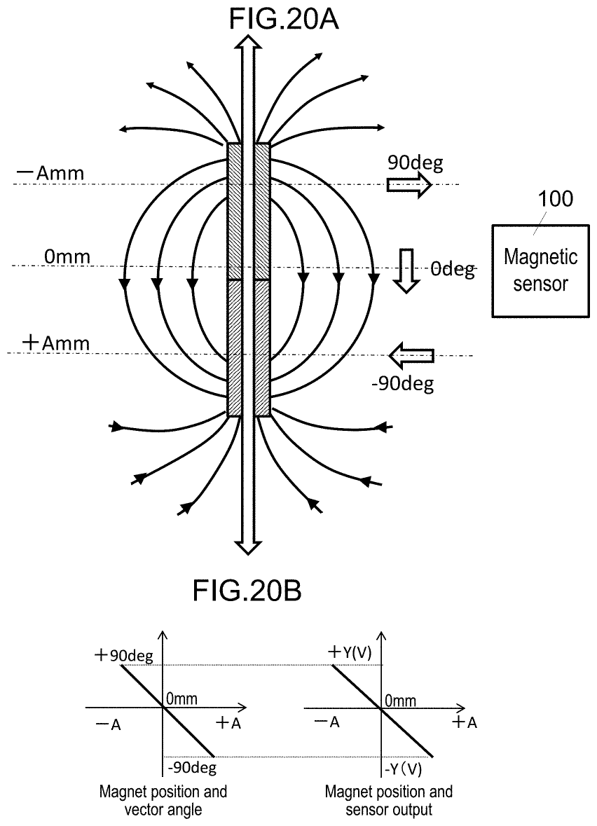

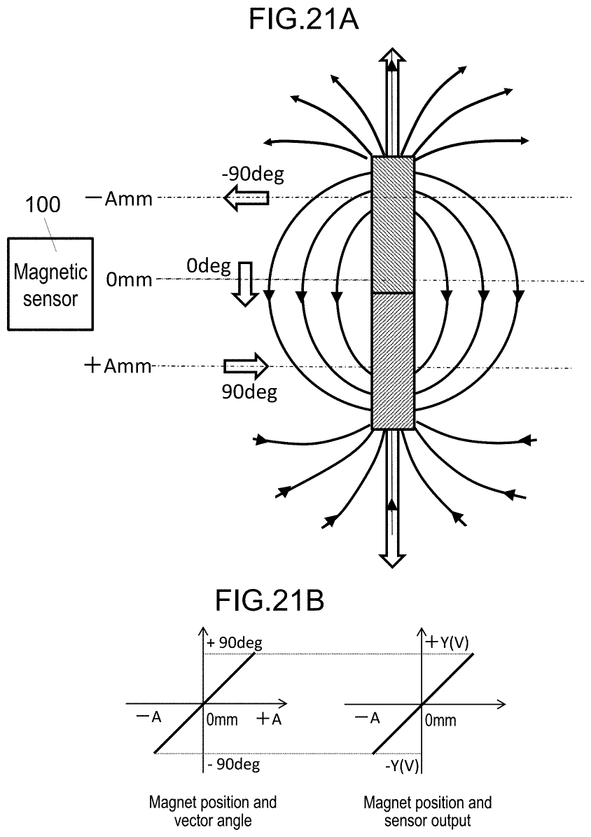

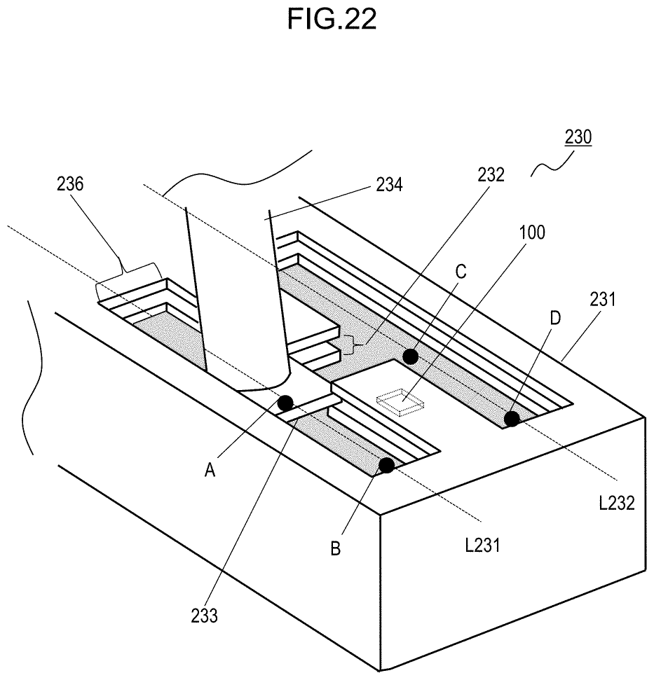

FIGS. 20A, 20B and FIGS. 21A, 21B are views describing a detection operation for detecting linear displacement of an object using the magnetic sensor of the present exemplary embodiment. FIGS. 20A, 20B illustrate a case where a magnet whose linear displacement is to be detected is placed on a left side of magnetic sensor 100. FIGS. 21A, 21B illustrate a case where the magnet whose linear displacement is to be detected is placed on a right side of magnetic sensor 100.

An operation in FIGS. 20A, 20B will be described below.

When the magnet moves along a displacement axis direction by +A mm, magnetic sensor 100 receives a magnetic vector angle of −90 degrees. In contrast, when the magnet moves along the displacement axis direction by −A mm, magnetic sensor 100 receives a magnetic vector angle of +90 degrees. The magnetic vector angle received by magnetic sensor 100 according to such axis-direction movement has a relationship between a displacement position of the magnet and the magnetic vector as illustrated in a left-hand view of FIG. 20B. Outputs of a first circuit block and a second circuit block are subjected to the operation (ARCTAN), whereby an output of magnetic sensor 100 according to this magnet movement, which indicates the vector angle, provides a substantially linear output with respect to the displacement position of the magnet as illustrated in a right-hand view of FIG. 20B.

In an operation in FIGS. 21A, 21B, when the magnet moves along the displacement axis direction by +A mm, magnetic sensor 100 receives the magnetic vector angle of +90 degrees. In contrast, when the magnet moves along the displacement axis direction by −A mm, magnetic sensor 100 receives the magnetic vector angle of −90 degrees. The magnetic vector angle received by magnetic sensor 100 according to such axis-direction movement has a relationship between a displacement position of the magnet and the magnetic vector as illustrated in a left-hand view of FIG. 21B. The outputs of the first circuit block and the second circuit block are subjected to the operation (ARCTAN), whereby the output of magnetic sensor 100 according to this magnet movement, which indicates the vector angle, provides a substantially linear output with respect to the displacement position of the magnet as illustrated in a right-hand view of FIG. 21B. Accordingly, disposition of FIGS. 20A, 20B and disposition of FIGS. 21A, 21B provide mutually reversed characteristics in output change of magnetic sensor 100.

### (Detection Device)

FIG. 22 is a schematic view illustrating detection device 230 using magnetic sensor 100 according to the present exemplary embodiment. Detection device 230 includes case 231, guide 232, detection target magnet 233, shaft 234 (shaft 234 can also be described as the shift lever), and magnetic sensor 100.

Case 231 includes slit 236 having a predetermined shape.

Slit 236 includes portions along straight line L231 (straight line L231 can be described as a first straight line) and straight line L232 (straight line L232 can be described as a second straight line). Straight line L231 and straight line L232 are parallel to each other. In FIG. 22, slit 236 has an H shape. Guide 232 is disposed on an inner wall of slit 236. The “guide” can be described as a “recess”.

Detection target magnet 233 is movably disposed in slit 236 along guide 232. In other words, detection target magnet 233 can move along straight line L232 and straight line L231. Also straight line L232 and straight line L231 can be described as a trajectory of movement of detection target magnet 233. Alternatively, such straight line L232, straight line L231, or the trajectory of movement of detection target magnet 233 can be described as a “detection lane” (or merely described as a “lane”). When the “lane” is used to describe, it can be described that case 231 includes first and second detection lanes parallel to each other.

Note that detection target magnet 233 may partially fit into guide 232, or detection target magnet 233 may be covered with, for example, resin and this resin may partially fit into guide 232. Alternatively, when shaft 234 is configured to be a lever mechanism, detection target magnet 233 may be moved by a link mechanism linked to the lever mechanism.

Shaft 234 is linked to detection target magnet 233, and when a user operates shaft 234, detection target magnet 233 moves along guide 232.

Magnetic sensor 100 is attached to case 231, is disposed between straight line L231 and straight line L232, and detects the linear displacement of detection target magnet 233 with the operations described in FIGS. 20A, 20B and FIGS. 21A, 21B.

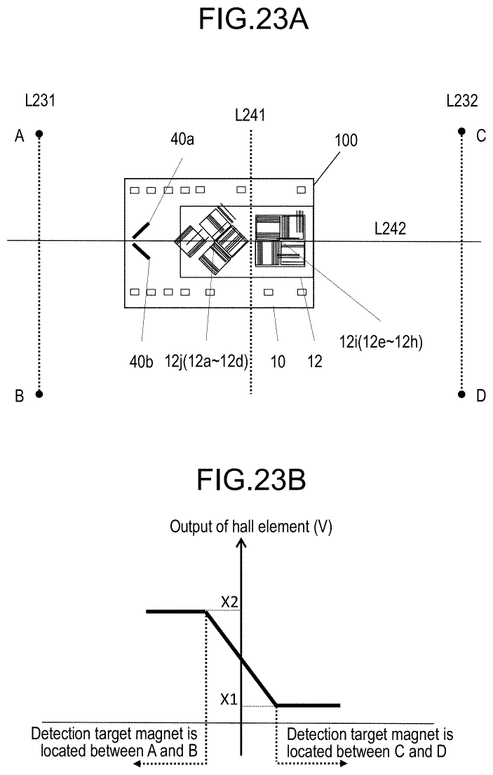

FIGS. 23A, 23B are views of a part of FIG. 22 viewed from an upper surface. In FIGS. 23A, 23B, configurations unnecessary for description are omitted. Further, a straight line passing through the middle between straight line L231 and straight line L232 is indicated as straight line L241. Here straight line L241 can be described as a straight line that is parallel to straight line L231, and is separated from straight line L231 and straight line L232 by an equal distance.

In detection device 230, first magnetic resistance element group 12i and second magnetic resistance element group 12j are placed so as to interpose straight line L241 therebetween. In other words, magnetic resistance element 12 is disposed at a position where straight line L241 passes through. On the other hand, first Hall element 40a and second Hall element 40b are provided at positions where straight line L241 does not pass through. In other words, first Hall element 40a and second Hall element 40b are provided while providing a certain distance from straight line L241.

With this configuration, with respect to the magnetic resistance element, even when detection target magnet 233 is located on any one of straight line L231 and straight line L232, a distance from a substantial center of each magnetic resistance to each straight line is constant. Therefore amplitude of a signal output from each magnetic resistance is substantially constant. For example, in FIG. 23A, detection target magnet 233 located at position A outputs a signal having the same amplitude as that of detection target magnet 233 located at position C from each magnetic resistance. That is, even when detection target magnet 233 is located to be separated in any of a right direction and a left direction of magnetic sensor 100, a position of detection target magnet 233 can be detected with high accuracy.

On the other hand, as illustrated in FIG. 23B, with respect to each Hall element, detection target magnet 233 passes through a position closer to first Hall element 40a and second Hall element 40b when detection target magnet 233 moves on straight line L231 than when detection target magnet 233 moves on straight line L232. Here a Hall element outputs a larger signal as the Hall element externally receives larger magnetic field strength. Hence a signal output from each Hall element when detection target magnet 233 moves on straight line L231 is larger than a signal output from each Hall element when detection target magnet 233 moves on straight line L232.

Accordingly, for example, threshold determination is performed on the signal output from each Hall element, whereby it is possible to determine which of the right and left directions of magnetic sensor 100 detection target magnet 233 is located to be separated. In other words, it is possible to determine which of the right and left sides of magnetic sensor 100 detection target magnet 233 is located.

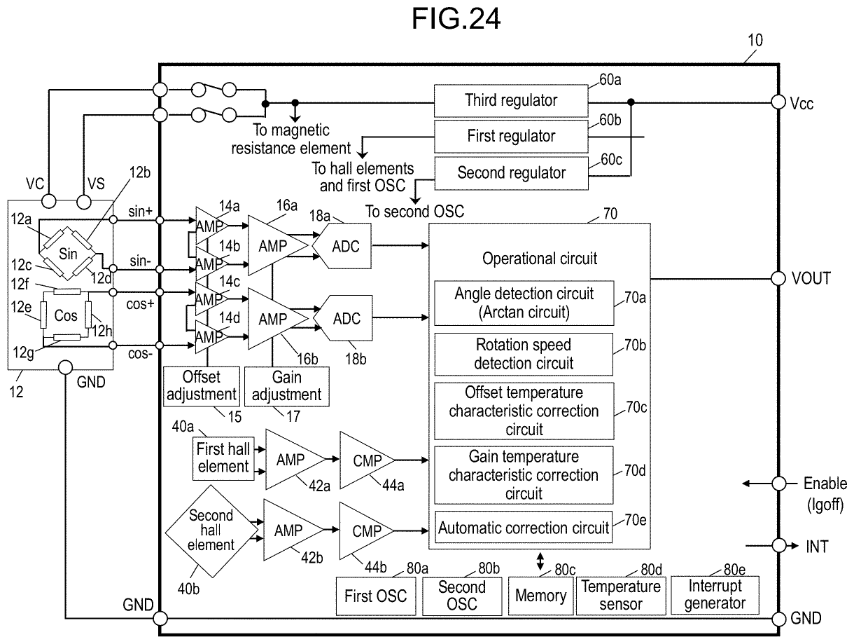

Magnetic sensor 100 described in FIG. 22 can be expressed as follows. Magnetic sensor 100 includes the detection circuit for receiving signals from the magnetic resistance element and the Hall element. Herein the detection circuit includes an output terminal (VOUT in FIG. 24) that externally outputs an output signal, after the signal input from the magnetic resistance element is subjected to at least one process selected from amplification, AD conversion, offset correction, and temperature characteristic correction. Furthermore, the detection circuit includes an interrupt output terminal (INT in FIG. 24) that outputs a first interrupt signal when the signal input from the Hall element is larger than a predetermined threshold. Herein the first interrupt signal is a signal indicating that detection target magnet 233 is located to be separated from magnetic sensor 100 in the first direction.

In addition, a second interrupt signal may be output when the signal input from the Hall element is smaller than the predetermined threshold. The second interrupt signal is a signal indicating that detection target magnet 233 is located to be separated from magnetic sensor 100 in the second direction opposite to the first direction.

As illustrated in FIG. 24, interrupt generator 80e disposed in detection circuit 10 generates the first and second interrupt signals. Interrupt generator 80e receives the signal from each Hall element through operational circuit 70, and performs the threshold determination on the signal, to generate the first or second interrupt signal. Note that “interrupt generator 80e” may be described as an “interrupt generation unit”.

Incidentally, in FIG. 13, magnetic sensor 100b in which magnetic resistance element 122 is disposed on magnetic resistance element 121 (magnetic resistance element 121 and magnetic resistance element 122 are disposed such that the centers thereof coincide with each other) has been described, but a configuration in which the centers of magnetic resistance element 121 and magnetic resistance element 122 coincide with each other is not limited to the above configuration.

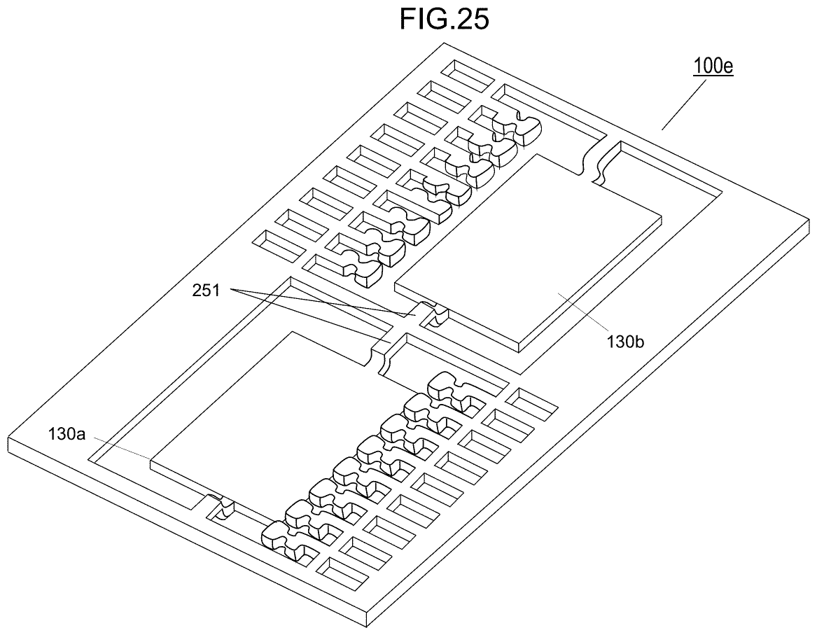

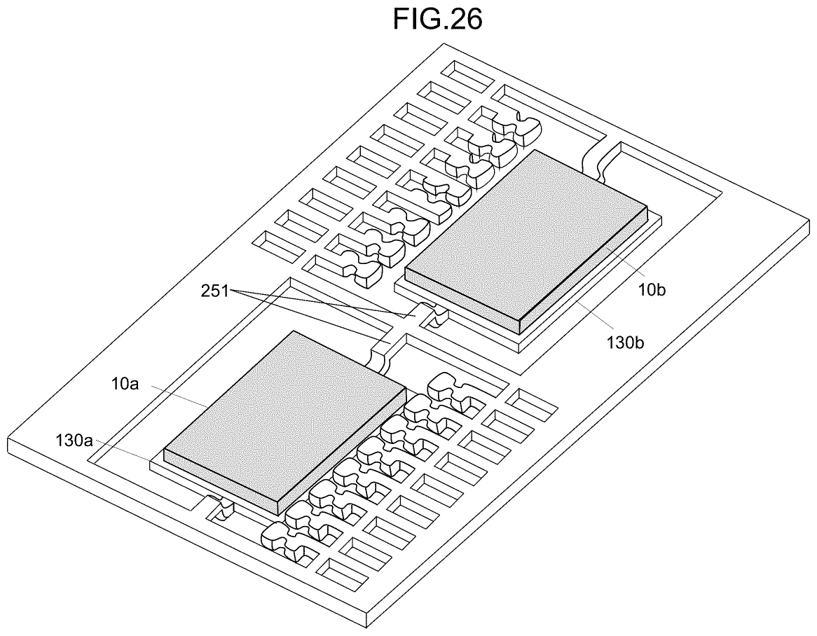

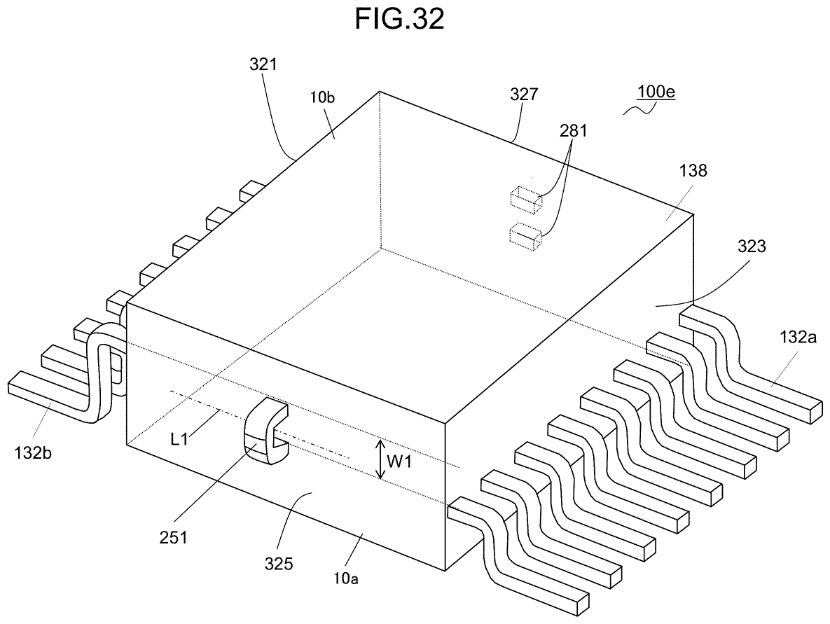

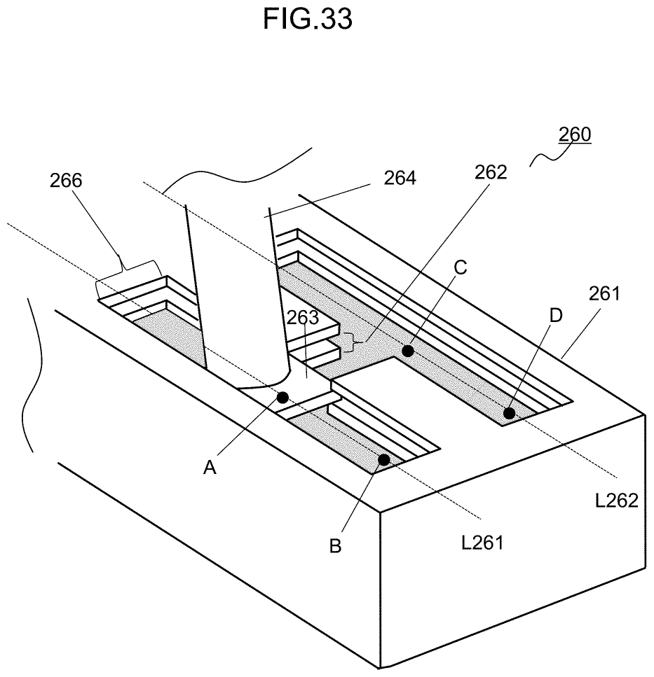

FIG. 26 to FIG. 32 describe another magnetic sensor 100e that can be adopted for causing the centers of magnetic resistance element 121 and magnetic resistance element 122 to substantially coincide with each other. Herein a manufacturing method of magnetic sensor 100e will be described with reference to FIG. 25 to FIG. 31. FIG. 32 is a perspective view of magnetic sensor 100e.

### (Manufacturing Method of Magnetic Sensor)

First, as illustrated in FIG. 25, die pad 130a and die pad 130b of magnetic sensor 100e are coupled to each other through coupling unit 251.

Next, as illustrated in FIG. 26, detection circuit 10a is disposed on die pad 130a. Detection circuit 10b is disposed on die pad 130b.

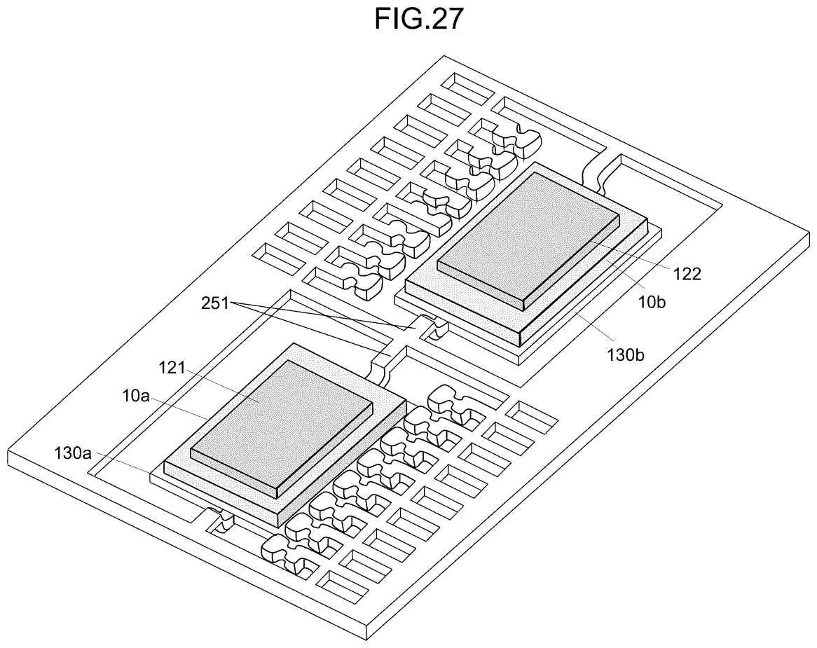

Next, as illustrated in FIG. 27, magnetic resistance element 121 is disposed on detection circuit 10a. Magnetic resistance element 122 is disposed on detection circuit 10b.

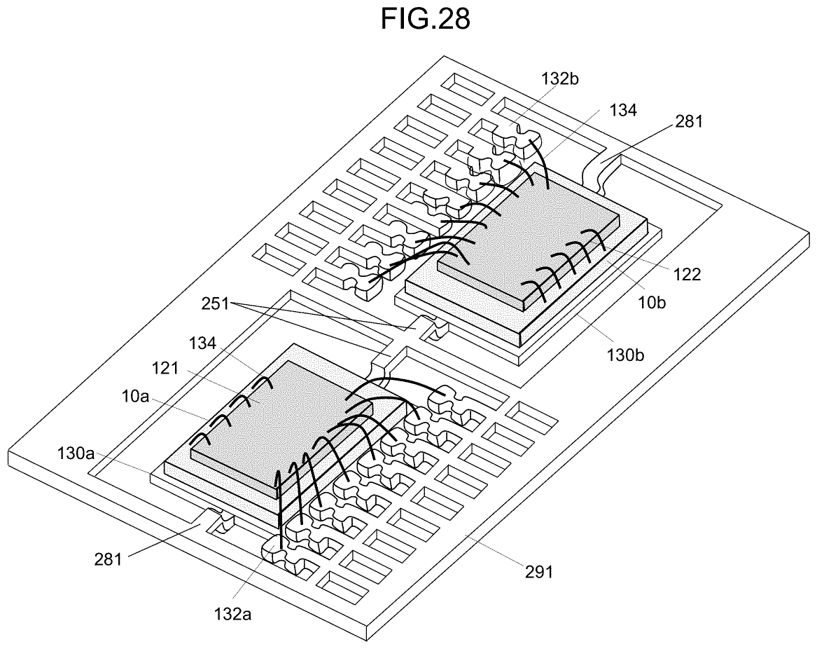

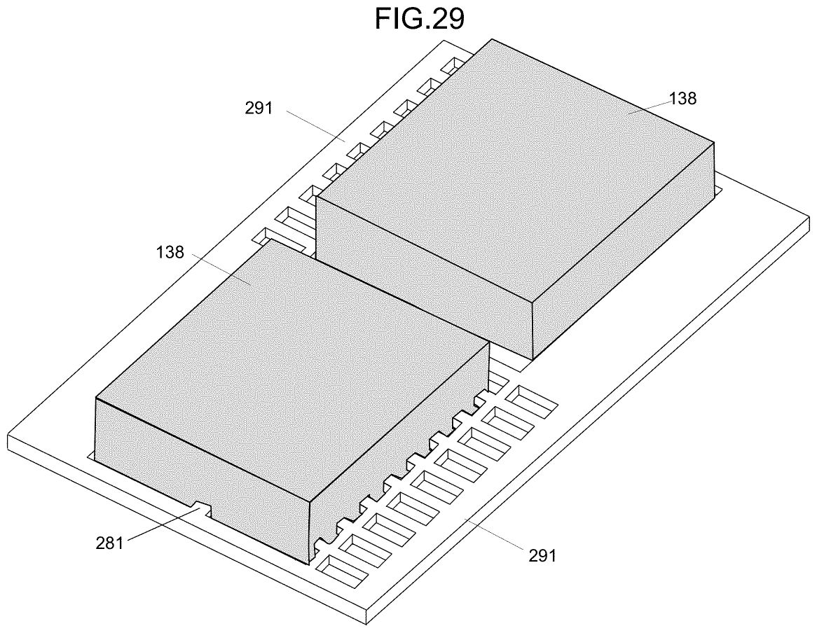

Next, as illustrated in FIG. 28, wires 134 achieves electrical connection between detection circuit 10a and magnetic resistance element 121, between detection circuit 10a and leads 132a, between detection circuit 10b and magnetic resistance element 122, and between detection circuit 10b and leads 132b.

Next, as illustrated in FIG. 29, sealing resin 138 resin-molds magnetic resistance elements 121, 122 and other components.

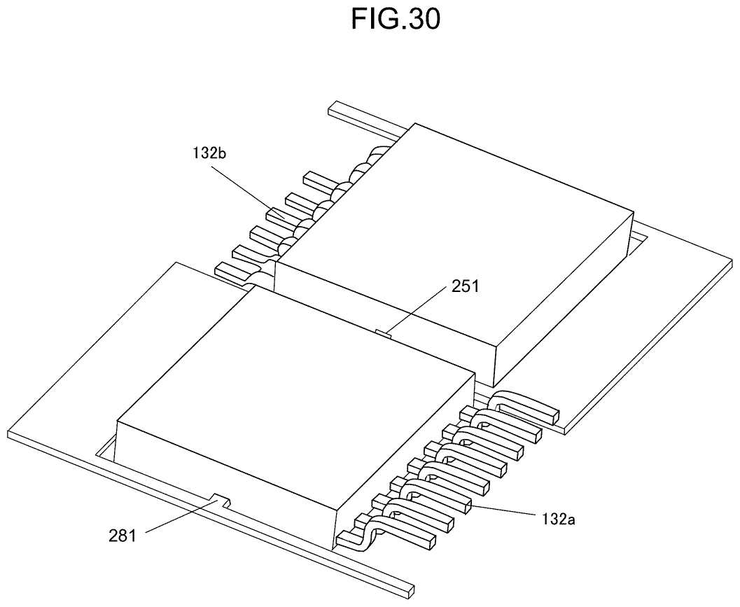

Next, as illustrated in FIG. 30, parts of tie bars 291 are cut away, and leads 132a, 132b are then bent.

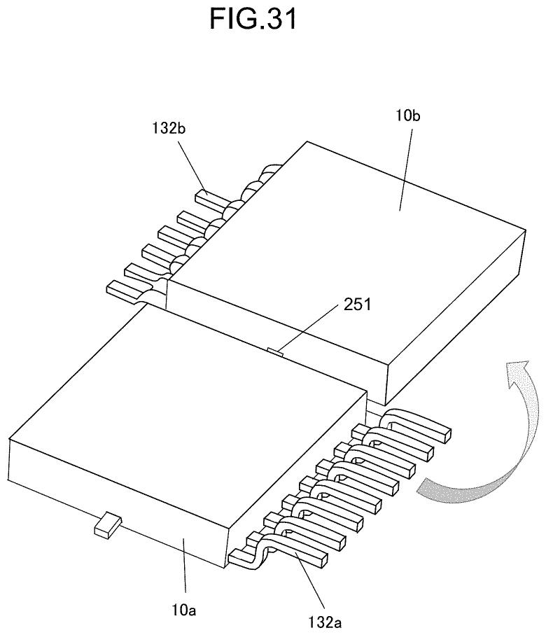

Next, as illustrated in FIG. 31, remaining tie bars 291 are cut away, and coupling unit 251 is bent, thereby forming magnetic sensor 100e in FIG. 32.

With this configuration, the center of magnetic resistance element 121 and the center of magnetic resistance element 122 can be made precisely close to each other, thereby preferably causing the signal obtained from magnetic resistance element 121 and the signal obtained from magnetic resistance element 122 to be substantially identical.

Magnetic sensor 100e is formed through manufacturing processes described above, and therefore has the following features.

Leads 132b electrically connected to detection circuit 10b are pulled out from first surface 321 of sealing resin 138, and leads 132a electrically connected to detection circuit 10b are pulled out from second surface 323 facing first surface 321 of sealing resin 138. Herein leads 132a connected to detection circuit 10a are pulled out at positions lower than positions where leads 132b connected to detection circuit 10b are pulled out, on the basis of a bottom surface of sealing resin 138. In other words, leads 132a connected to detection circuit 10a and leads 132b connected to detection circuit 10b are pulled out at heights different from each other, on the basis of the bottom surface (or an upper surface) of sealing resin 138. Note that this height difference is indicated as “W1” in FIG. 32.

Coupling unit 251 is pulled out from third surface 325 perpendicular to first surface 321 and second surface 323, and has an arch shape. Note that the shape of coupling unit 251 is not limited to the arch. For example, when a part of coupling unit 251 having been bent is cut, the shape may be an arch shape that is partially lost (an arch shape whose top portion is removed). That is, it can be expressed that coupling unit 251 includes portions pulled out from at least two positions of third surface 325. Further, as illustrated by dashed line L1 in FIG. 32, a boundary may remain below the arch formed by coupling unit 251 (in other words, between two positions of third surface 325 where coupling unit 251 is pulled out) in sealing resin 138. The boundary is a trace remained when sealing resin 138 sealing magnetic resistance element 121 and sealing resin 138 sealing magnetic resistance element 122 are bonded together, as illustrated in FIG. 31. Herein the “boundary” can mean a state of producing a line remained in the resin and/or a gap in a part of the resin. Further, it can be described that the “boundary” is positioned between die pad 130a and die pad 130b.

From fourth surface 327 facing third surface 325 from which coupling unit 251 is pulled out, supporters 281 coupling die pads 130a, 130b to die bars 291 are pulled out.

Note that in the above detailed description of the embodiment with reference to FIGS. 25 to 30, magnetic resistance elements (121, 122) are respectively disposed on detection circuits (10a, 10b) disposed on die pads 130. However, detection circuits (10a, 10b) may respectively be disposed on magnetic resistance elements (121, 122) disposed on die pads 130. With this configuration, magnetic resistance element 121 and magnetic resistance element 122 are disposed closer to each other, whereby detection magnetic fields input into those magnetic resistance elements are similar to each other. Therefore similarity between output signals is more improved.

Detection device 230 using magnetic sensor 100 according to the present exemplary embodiment has been described with reference to FIG. 22, but the configuration of the detection device is not limited to this configuration.

### Fourth Exemplary Embodiment

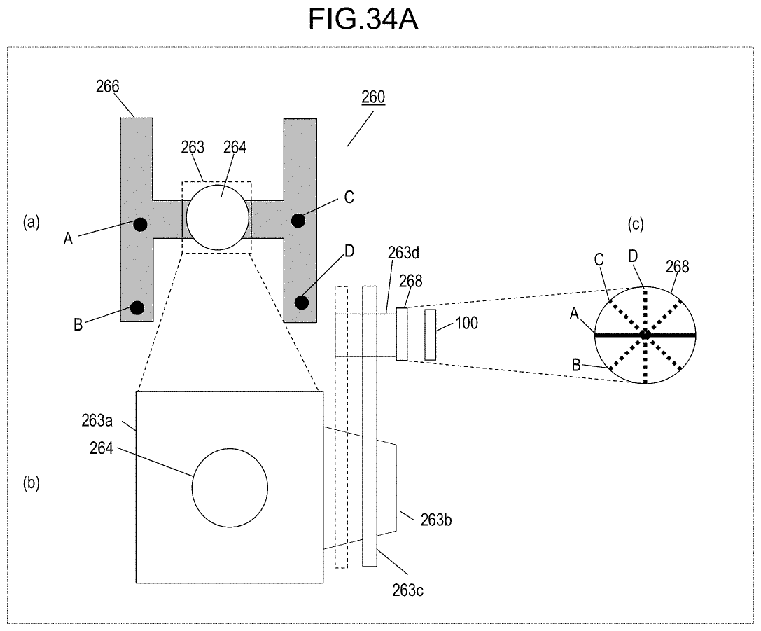

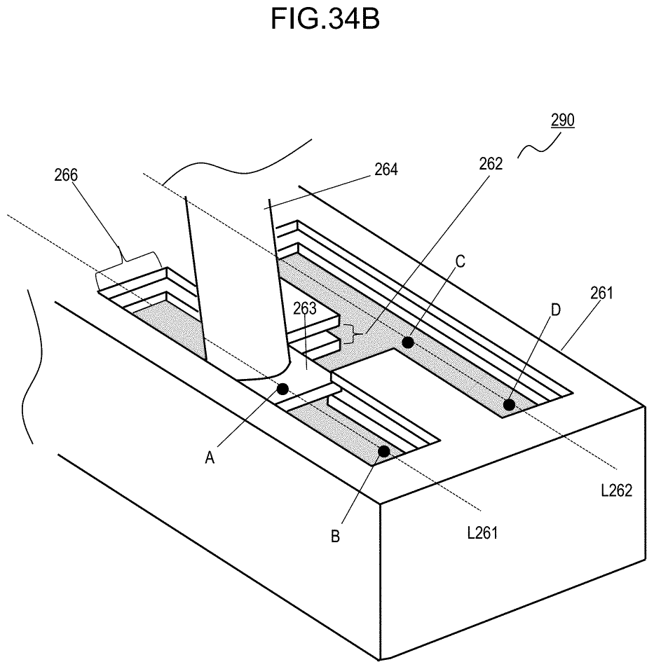

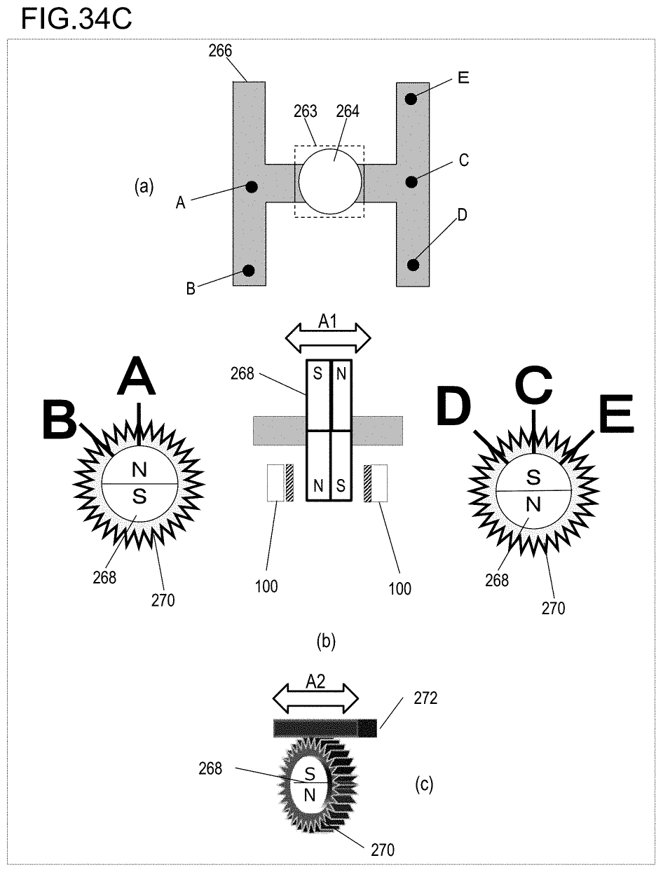

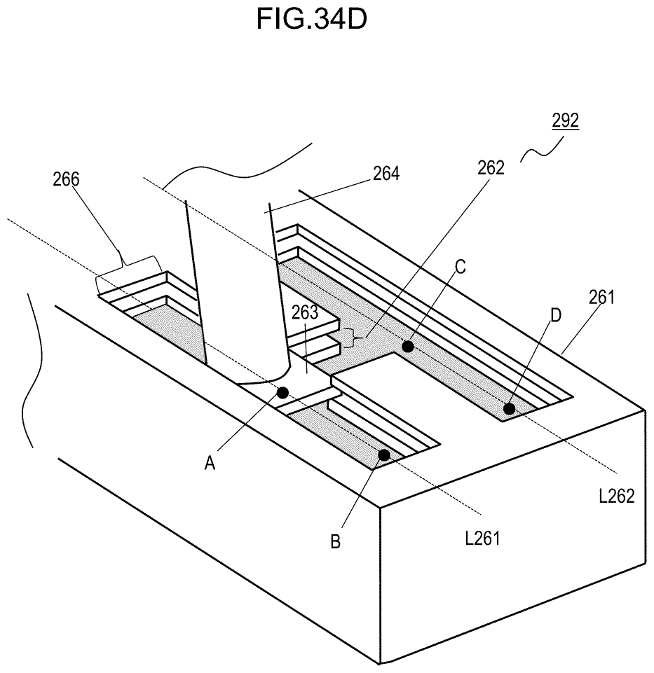

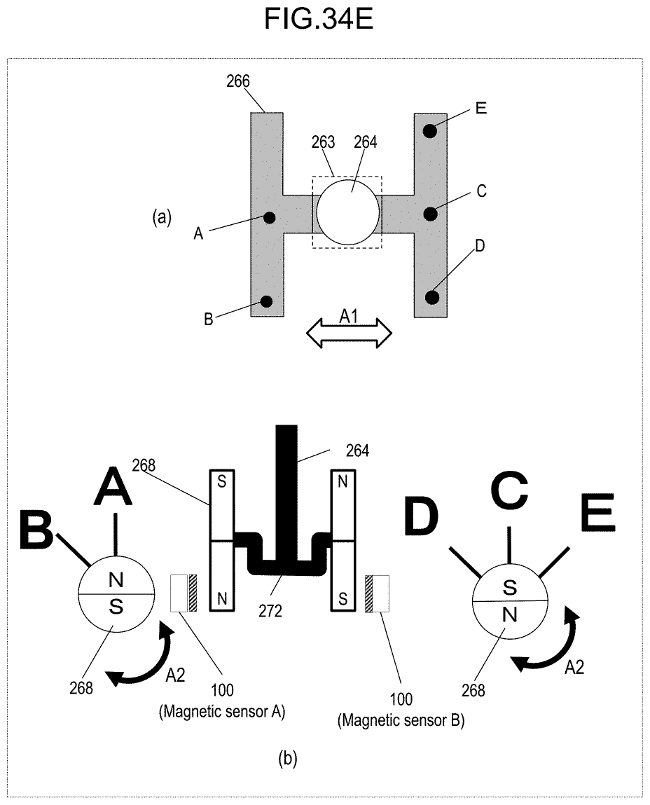

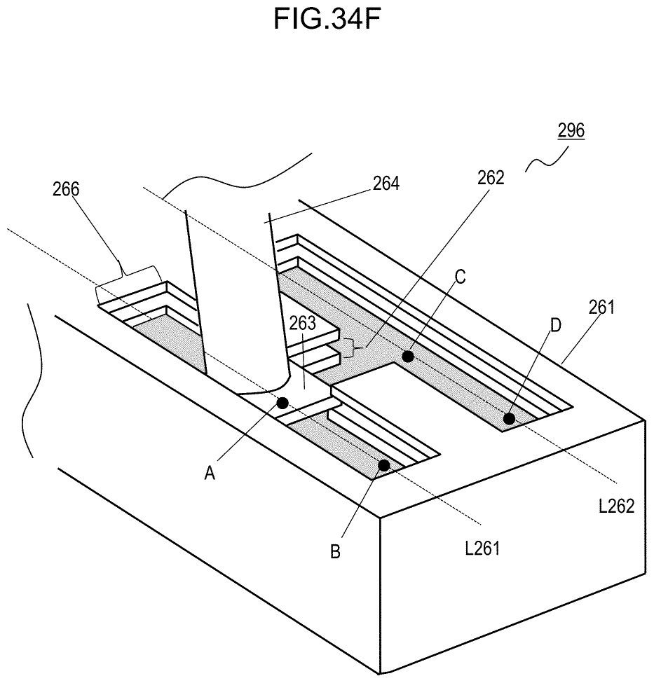

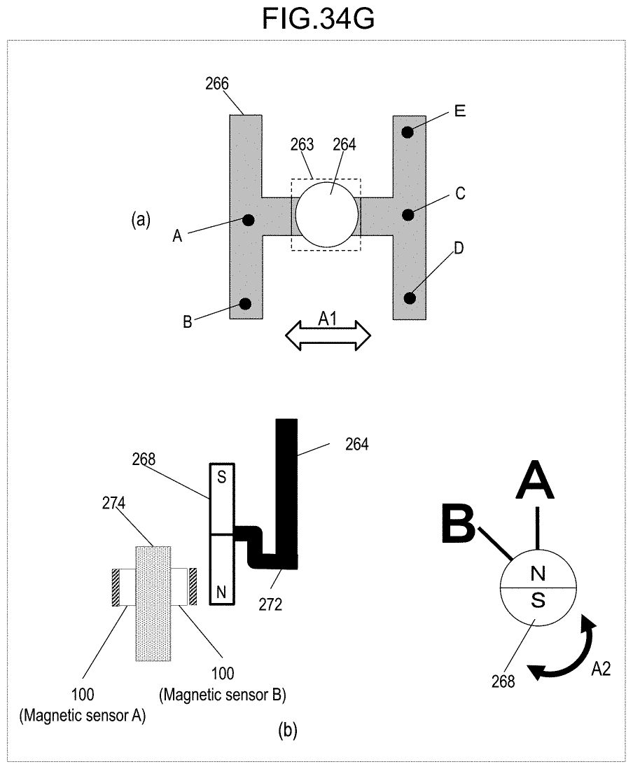

FIG. 33 is a perspective view of (position) detection device 260 according to a fourth exemplary embodiment. FIG. 34A is a top view of a part of detection device 260. Note that, in FIG. 34A, configurations unnecessary for description are omitted as appropriate. In FIG. 34A, part (a) is a view illustrating a part of an upper surface of detection device 260, part (b) is an enlarged view of link mechanism 263 and shaft 264, and part (c) is an enlarged view of detection target magnet 268.

Detection device 260 includes case 261, guide 262, link mechanism 263, shaft 264 (shaft 264 can also be described as a shift lever), and magnetic sensor 100.

Case 261 includes slit 266 having a predetermined shape.

Slit 266 includes portions along straight line L261 (straight line L261 can be described as a first straight line) and straight line L262 (straight line L262 can be described as a second straight line). Straight line L261 and straight line L262 are parallel to each other. In FIG. 33, slit 266 has an H shape. Guide 262 is disposed on an inner wall of slit 266. The “guide” can be described as a “recess”.

Shaft 264 is coupled to link mechanism 263. When a user operates shaft 264, link mechanism 263 (more precisely, a part of a member configuring link mechanism 263) moves along guide 262.

Link mechanism 263 includes supporter 263a connected to shaft 264, first movable body 263b connected to supporter 263a, belt 263c connected to first movable body 263b, second movable body 263d connected to belt 263c, and detection target magnet 268 connected to second movable body 263d.

Supporter 263a is movably disposed in slit 266 along guide 262. In other words, supporter 263a can move along straight line L262 and straight line L261. Also straight line L262 and straight line L261 can be described as a trajectory of movement of supporter 263a. Alternatively, such straight line L262, straight line L261, or the trajectory of movement of supporter 263a can be described as a “detection lane” (or merely described as a “lane”). When the “lane” is used to describe, it can be described that case 261 includes first and second detection lanes parallel to each other.

First movable body 263b is configured to convert vertical movement of supporter 263a into rotary movement. First movable body 263b is formed in a trapezoidal cross-sectional shape whose inner circumference closer to supporter 263a is wide and whose outer circumference is narrow, as a shape in which movement of shaft 264 in right and left directions changes a rotary amount of first movable body 263b.

Belt 263c is configured with a belt that connects first movable body 263b to second movable body 263d, and transmits rotary motion of first movable body 263b to second movable body 263d.

Second movable body 263d is configured to perform rotary motion in response to motive power transmission of belt 263c, and has a columnar shape. Further, second movable body 263d is connected to detection target magnet 268, thereby providing a change in magnetic field of detection target magnet 268 to magnetic sensor 100. As described above, shaft 264 (shift lever) is coupled with link mechanism 263, and right-left movement of shaft 264 changes the rotary amount of the second movable body. With this configuration, a difference in rotation angle of the magnet is made between position B and position D. As a result, single magnetic sensor 100 can determine positions from position A to position D.

Note that such link mechanism 263 can be referred to as a “variable speed pulley”.

Note that when such link mechanism 263 is used, the Hall element (and a circuit configuration used for detecting an output from the Hall element) in magnetic sensor 100 is not essential.

### (First Modification)

FIG. 34B is a perspective view of (position) detection device 290 of a first modification according to the present exemplary embodiment. FIG. 34C is a top view of a part of detection device 290. Note that, in FIG. 34C, configurations unnecessary for description are omitted as appropriate.

Detection device 290 includes case 261, guide 262, link mechanism 263, shaft 264 (shaft 264 can also be described as a shift lever), and magnetic sensors.

Case 261 includes slit 266 having a predetermined shape.

Slit 266 includes portions along straight line L261 (straight line L261 can be described as a first straight line) and straight line L262 (straight line L262 can be described as a second straight line). Straight line L261 and straight line L262 are parallel to each other. In FIG. 33, slit 266 has an H shape. Guide 262 is disposed on an inner wall of slit 266. The “guide” can be described as a “recess”.

Shaft 264 is coupled to link mechanism 263. When a user operates shaft 264, link mechanism 263 (more precisely, a part of a member configuring link mechanism 263) moves along guide 262.

Link mechanism 263 includes a supporter, shaft 272 interlocked with the supporter, gear wheel 270 interlocked with shaft 272, and detection target magnet 268 supported by gear wheel 270.

Supporter 263a is movably disposed in slit 266 along shaft 272. In other words, supporter 263a can move along straight line L262 and straight line L261. Also straight line L262 and straight line L261 can be described as a trajectory of movement of supporter 263a. Alternatively, such straight line L262, straight line L261, or the trajectory of movement of supporter 263a can be described as a “detection lane” (or merely described as a “lane”). When the “lane” is used to describe, it can be described that case 261 includes first and second detection lanes parallel to each other.

Gear wheel 270 moves in a direction indicated by arrow A1 in FIG. 34C interlocked with movement of supporter 263a from a side of neutral C to a side of home A. This movement changes a distance between magnetic sensor 100 on the home side and gear wheel 270 (detection target magnet 268) or a distance between magnetic sensor 100 on the neutral side and gear wheel 270 (detection target magnet 268). Further, gear wheel 270 rotates interlocked with shaft 272. Specifically, shaft 272 moves in a direction of arrow A2 in FIG. 34C when supporter 263a moves between A and B or between E and D. Gear wheel 270 rotates interlocked with this movement of shaft 272.

Note that a mechanism for detecting rotation of gear wheel 270 (detection target magnet 268) with magnetic sensor 100 is the same as rotation detection device 150B in FIG. 2C. Accordingly it can also be described that detection device 290 includes rotation detection device 150B in FIG. 2C.

Table 1 indicates an output of magnetic sensor 100 included in detection device 290 for each position of supporter 263a.

TABLE 1

| | Angle value of | | | Angle value of | |
|---|---|---|---|---|---|
| Supporter | home-side | | | neutral-side | Supporter |
| position | magnetic sensor | Hall output | Shift position | magnetic sensor | output |
| A | 0 | High | C | 180 | Low |
| B | 45 | High | D | 225 | Low |
| E | −45 | High | E | 135 | Low |
| C | 0 | Low | A | 180 | High |
| D | 45 | Low | B | 225 | High |
| E | −45 | Low | E | 135 | High |

It is possible to determine whether supporter 263a (or shaft 264) is located on the home side or on the neutral side using the output of the Hall element of magnetic sensor 100. Specifically, when supporter 263a is located on the home side, a distance between magnetic sensor 100 on the home side and gear wheel 270 (detection target magnet 268) decreases, thereby causing the output of the Hall element included in magnetic sensor 100 on the home side to be High. Accordingly when the output of the Hall element is High, the position of supporter 263a (shaft 264) can be specified to be either A or B. At this time, by further using the output of magnetic sensor 100 on the home side, supporter 263a (shaft 264) can be specified to be located at which of A and B.

On the other hand, when supporter 263a is located on the neutral side, the distance between magnetic sensor 100 on the home side and gear wheel 270 (detection target magnet 268) increases, thereby causing the output of the Hall element included in magnetic sensor 100 on the home side to be Low. Accordingly when the output of the Hall element included in magnetic sensor 100 on the home side is Low, the position of supporter 263a (shaft 264) can be specified to be any one of C, D, and E. At this time, by further using the output of magnetic sensor 100 on the neutral side, supporter 263a (shaft 264) can be specified to be located at which of C, D, and E.

Furthermore, in detection device 290, since a difference of 180 degrees is always secured between the output of magnetic sensor 100 on the home side and the output of magnetic sensor 100 on the neutral side, it is possible to monitor whether detection device 290 is abnormal, by monitoring whether the difference between two outputs is 180 degrees. With this configuration, detection device 290 achieves high reliability.

### (Second Modification)

FIG. 34D is a perspective view of (position) detection device 292 of a second modification according to the present exemplary embodiment. FIG. 34E is a top view of a part of detection device 292. Note that, in FIG. 34D, configurations unnecessary for description are omitted as appropriate.

Detection device 292 includes case 261, guide 262, link mechanism 263, shaft 264 (shaft 264 can also be described as a shift lever), and magnetic sensor 100.

Case 261 includes slit 266 having a predetermined shape.

Slit 266 includes portions along straight line L261 (straight line L261 can be described as a first straight line) and straight line L262 (straight line L262 can be described as a second straight line). Straight line L261 and straight line L262 are parallel to each other. In FIG. 34D, slit 266 has an H shape. Guide 262 is disposed on an inner wall of slit 266. The “guide” can be described as a “recess”.

Shaft 264 is coupled to link mechanism 263. When a user operates shaft 264, link mechanism 263 (more precisely, a part of a member configuring link mechanism 263) moves along guide 262.

Link mechanism 263 includes a supporter, shaft 272 interlocked with the supporter, and detection target magnet 268 supported by shaft 272.

The supporter is movably disposed in slit 266 along shaft 272. In other words, supporter 263a can move along straight line L262 and straight line L261. Also straight line L262 and straight line L261 can be described as a trajectory of movement of supporter 263a. Alternatively, such straight line L262, straight line L261, or the trajectory of movement of supporter 263a can be described as a “detection lane” (or merely described as a “lane”). When the “lane” is used to describe, it can be described that case 261 includes first and second detection lanes parallel to each other.

Shaft 272 moves in a direction indicated by arrow A1 in FIG. 34E interlocked with movement of supporter 263a from a neutral side to a home side. This movement changes a distance between magnetic sensor 100 on the home side and detection target magnet 268 or a distance between magnetic sensor 100 on the neutral side and detection target magnet 268.

Further, detection target magnet 268 rotates interlocked with shaft 272. Specifically, since shaft 272 has a crank shape, shaft 272 moves along a direction of arrow A2 in FIG. 34E when supporter 263a moves between A and B or between E and D. Detection target magnet 268 rotates interlocked with this movement of shaft 272.

Note that a basic configuration of a mechanism for detecting rotation of detection target magnet 268 with magnetic sensor 100 is the same as rotation detection device 150b in FIG. 2B, although the detection target magnet is configured with two pieces separated from each other. With the detection target magnet configured with two pieces separated from each other, each of magnetic sensor 100 on the neutral side and magnetic sensor 100 on the home side can be disposed at a center of corresponding detection target magnet 268. With this configuration, detection device 292 achieves high detection accuracy.

An output of magnetic sensor 100 included in detection device 292 is the same as that indicated in Table 1, whereby a position of supporter 263a (shaft 264) can be specified based on the output of magnetic sensor 100 similar to detection device 290.

### (Third Modification)

FIG. 34F is a perspective view of (position) detection device 296 of a third modification according to the present exemplary embodiment. FIG. 34G is a top view of a part of detection device 296. Note that, in FIG. 34F, configurations unnecessary for description are omitted as appropriate.

Detection device 296 includes case 261, guide 262, link mechanism 263, shaft 264 (shaft 264 can also be described as a shift lever), and magnetic sensor 100.

Case 261 includes slit 266 having a predetermined shape.

Slit 266 includes portions along straight line L261 (straight line L261 can be described as a first straight line) and straight line L262 (straight line L262 can be described as a second straight line). Straight line L261 and straight line L262 are parallel to each other. In FIG. 34F, slit 266 has an H shape. Guide 262 is disposed on an inner wall of slit 266. The “guide” can be described as a “recess”.

Shaft 264 is coupled to link mechanism 263. When a user operates shaft 234, link mechanism 263 (more precisely, a part of a member configuring link mechanism 263) moves along guide 262.

Link mechanism 263 includes a supporter, shaft 272 interlocked with the supporter, and detection target magnet 268 supported by shaft 272.

The supporter is movably disposed in slit 266 along shaft 272. In other words, supporter 263a can move along straight line L262 and straight line L261. Also straight line L262 and straight line L261 can be described as a trajectory of movement of supporter 263a. Alternatively, such straight line L262, straight line L261, or the trajectory of movement of supporter 263a can be described as a “detection lane” (or merely described as a “lane”). When the “lane” is used to describe, it can be described that case 261 includes first and second detection lanes parallel to each other.

Shaft 272 moves in a direction indicated by arrow A1 in FIG. 34G interlocked with movement of supporter 263a from a neutral side to a home side. This movement changes a distance between magnetic sensor 100 on the home side and detection target magnet 268 or a distance between magnetic sensor 100 on the neutral side and detection target magnet 268.

Further, detection target magnet 268 rotates interlocked with shaft 272. Specifically, since shaft 272 has a crank shape, shaft 272 rotates along a direction of arrow A2 in FIG. 34G when supporter 263a moves between A and B or between E and D. Detection target magnet 268 rotates interlocked with this movement of shaft 272.

An output of magnetic sensor 100 included in detection device 296 is the same as that indicated in Table 1, whereby a position of supporter 263a (shaft 264) can be specified based on the output of magnetic sensor 100 similar to detection device 290. Furthermore, in detection device 296, magnetic sensor 100 on the home side and magnetic sensor 100 on the neutral side are disposed to face each other through substrate 274, whereby two magnetic sensors can perform detection with single detection target magnet 268. This achieves downsizing of the detection device. In addition, since a difference of 180 degrees is always secured between the outputs of the magnetic sensors, it is possible to monitor whether detection device 290 is abnormal, by monitoring whether the difference between two outputs is 180 degrees. With this configuration, detection device 290 achieves high reliability.

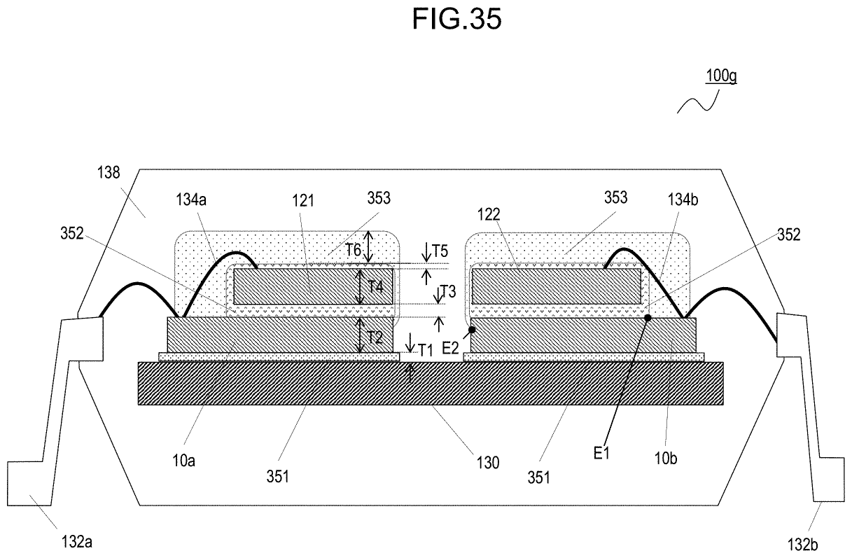

Incidentally, the front views of the magnetic sensors are described with reference to FIG. 10, FIG. 11, and other drawings. A connection configuration of die pad 130, detection circuits 10a, 10b, and magnetic resistance elements 121, 122 will further be described in detail with reference to FIG. 35 to FIG. 40.

In the drawings, thickness T1 is a thickness of first resin 351. Thickness T2 is a thickness of each of detection circuits 10a, 10b. Thickness T3 is a thickness of second resin 352 between die pad 130 and detection circuits 10a, 10b. Thickness T4 is a thickness of each of magnetic resistance elements 121, 122. Thickness T5 is a thickness of second resin 352 between the magnetic resistance elements and third resin 353. Thickness T6 is a thickness of third resin 353 between third resin 353 and sealing resin 138.

### (Fourth Modification)

FIG. 35 is a front view of magnetic sensor 100g according to a fourth modification of the present exemplary embodiment.

Magnetic sensor 100g includes die pad 130, detection circuits 10a, 10b, magnetic resistance elements 121, 122, leads 132a, 132b, wires 134, 134b, sealing resin 138, first resin 351, second resin 352, and third resin 353.

First resin 351 is a material for connecting die pad 130 and detection circuits 10a, 10b. Specifically, first resin 351 is a die bonding material formed from an epoxy material. Here an elastic modulus of first resin 351 is set to be 8 GPa.

Second resin 352 is a material for connecting detection circuits 10a, 10b and magnetic resistance elements 121, 122. Specifically, second resin 352 is a die bonding material formed from a silicon-based material. Here an elastic modulus of second resin 352 is set to be 5 MPa.

Third resin 353 is a material for connecting magnetic resistance elements 121, 122 and sealing resin 138. Specifically, third resin 353 is a chip coating material. Here an elastic modulus of third resin 353 is set to be 20 Mpa.

Second resin 352 is smaller in elastic modulus than first resin 351. Third resin 353 is larger in elastic modulus than second resin 352.

Thickness T3 is larger than thickness T1. Thickness T3 is larger than thickness T5. Thickness T6 is larger than thickness T5.

Second resin 352 covers magnetic resistance elements 121, 122. End E1 of second resin 352 is brought in contact with an upper surface of detection circuit 10b at a portion on an outer side than magnetic resistance element 122.

Third resin 353 covers second resin 352. End E2 of third resin 353 is brought in contact with a side surface of detection circuit 10b.

### (Fifth Modification)

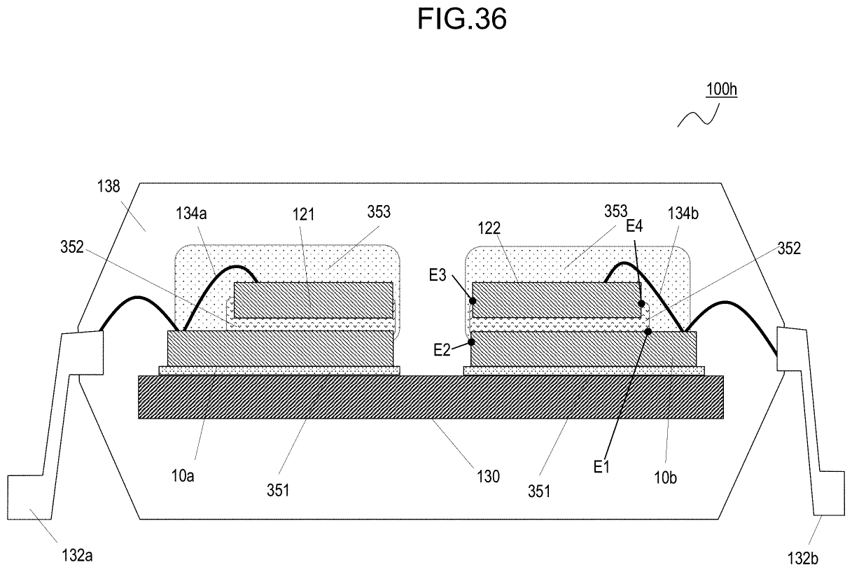

FIG. 36 is a front view of magnetic sensor 100h according to a fifth modification of the present exemplary embodiment. Hereinafter, a description will be made focusing on differences from magnetic sensor 100g in FIG. 35.

Magnetic sensor 100h includes die pad 130, detection circuits 10a, 10b, magnetic resistance elements 121, 122, leads 132a, 132b, wires 134, 134b, sealing resin 138, first resin 351, second resin 352, and third resin 353. The description will be made below focusing on the differences from magnetic sensor 100g in FIG. 35.

Second resin 352 covers lower surfaces and parts of magnetic resistance elements 121, 122. End E3 and end E4 of second resin 352 are brought in contact with side surfaces of magnetic resistance element 122.

### (Sixth Modification)

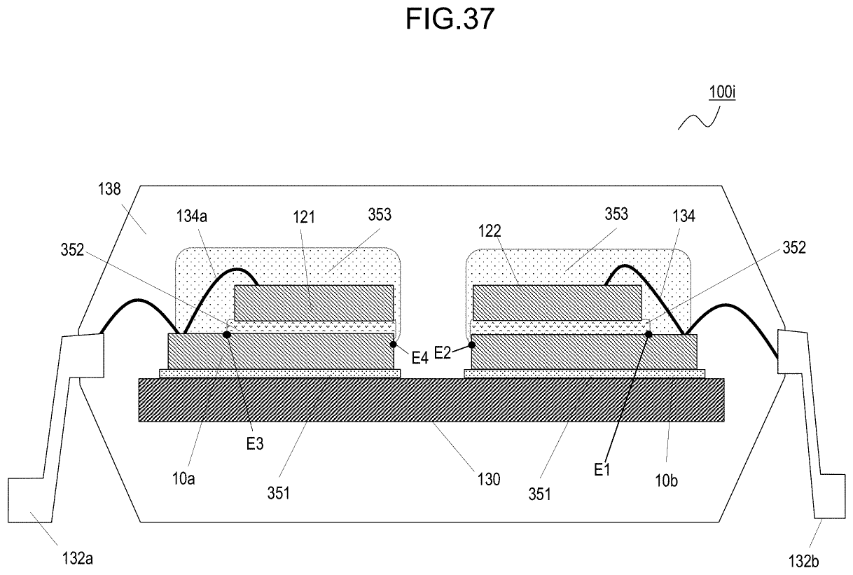

FIG. 37 is a front view of magnetic sensor 100i according to a sixth modification of the present exemplary embodiment. Hereinafter, a description will be made focusing on differences from magnetic sensor 100g in FIG. 35.

Magnetic sensor 100i includes die pad 130, detection circuits 10a, 10b, magnetic resistance elements 121, 122, leads 132a, 132b, wires 134, 134b, sealing resin 138, first resin 351, second resin 352, and third resin 353.

Second resin 352 covers lower surfaces of magnetic resistance elements 121, 122. End E3 and end E4 of second resin 352 are brought in contact with side surfaces of magnetic resistance element 122.

### (Seventh Modification)

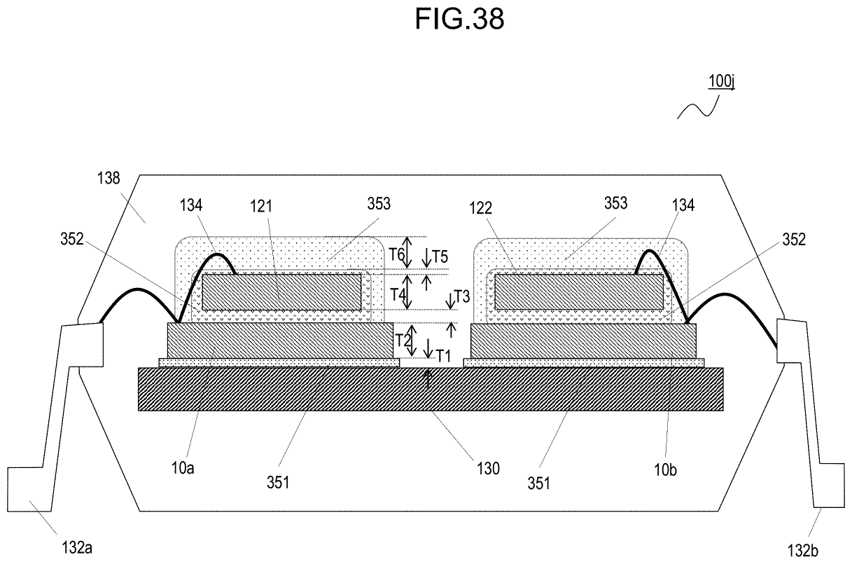

FIG. 38 is a front view of magnetic sensor 100j according to a seventh modification of the present exemplary embodiment. Magnetic sensor 100j is different from magnetic sensor 100g in FIG. 35 in that centers of magnetic resistance elements 121, 122 coincide with centers of detection circuits 10a, 10b, respectively.

### (Eighth Modification)

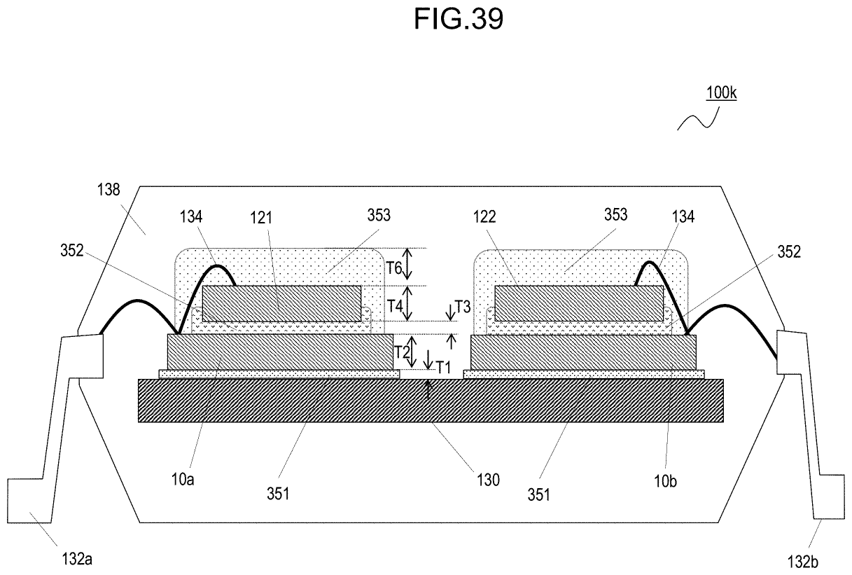

FIG. 39 is a front view of magnetic sensor 100k according to an eighth modification of the present exemplary embodiment. Magnetic sensor 100k is different from magnetic sensor 100g in FIG. 35 in that centers of magnetic resistance elements 121, 122 coincide with centers of detection circuits 10a, 10b, respectively.

### (Ninth Modification)

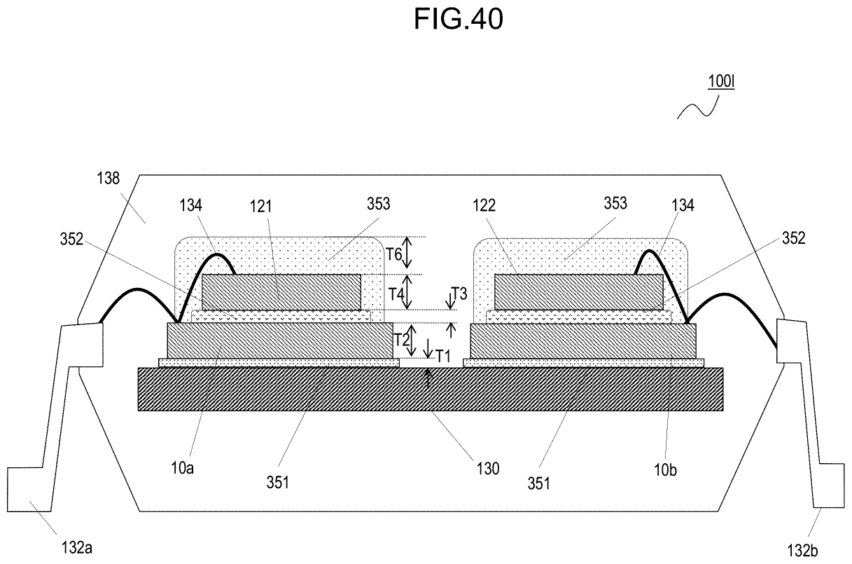

FIG. 40 is a front view of magnetic sensor 100l according to a ninth modification of the present exemplary embodiment. Magnetic sensor 100l is different from magnetic sensor 100g in FIG. 35 in that centers of magnetic resistance elements 121, 122 coincide with centers of detection circuits 10a, 10b, respectively.

Those configurations illustrated in FIG. 35 to FIG. 40 can provide an effect that lessens stress imposed on the magnetic resistance element upon assembling the magnetic sensor, and an effect that lessens stress transmitted to the magnetic resistance element upon mounting the magnetic sensor through, for example, soldering and upon imposing external stress after mounting. Furthermore, those configurations can prevent moisture from entering the magnetic resistance element from the outside. This provides an effect for enhancing durability of the magnetic sensor. In addition, a vibration isolation effect of the magnetic resistance element against external vibration can also be obtained.

Note that the above-described examples provide the configurations for lessening stress on the magnetic resistance element. However, by replacing the magnetic resistance element with the detection circuit, configurations for lessening stress on the detection circuit may be provided. In the present example, the configuration for lessening stress with the elastic modulus of each resin material has been described, but it is possible to adopt a configuration in which a coefficient of thermal conductivity of each resin material is properly provided, and generated heat inside the magnetic sensor is transmitted to the outside.

### INDUSTRIAL APPLICABILITY

A position detection device of the present disclosure has high accuracy or high reliability, and therefore is useful as, for example, a magnetic sensor used for detecting a steering angle and the like of a vehicle.

### REFERENCE MARKS IN THE DRAWINGS

10, 10a, 10b: detection circuit
12: magnetic resistance element
12a: first sine magnetic resistance element
12b: second sine magnetic resistance element
12c: third sine magnetic resistance element
12d: fourth sine magnetic resistance element
12e: first cosine magnetic resistance element
12f: second cosine magnetic resistance element
12g: third cosine magnetic resistance element
12h: fourth cosine magnetic resistance element
12i: first magnetic resistance element group
12j: second magnetic resistance element group
14a: first amplifier
14b: second amplifier
14c: third amplifier
14d: fourth amplifier
15: offset adjustment circuit
16a: first differential amplifier
16b: second differential amplifier
17: gain adjustment circuit
18a: first AD converter
18b: second AD converter
40a: first Hall element
40b: second Hall element
42a: first amplifier
42b: second amplifier
44a: first comparator
44b: second comparator
60a: third regulator
60b: first regulator
60c: second regulator
70: operational circuit
70a: angle detection circuit
70b: rotation speed detection circuit
70c: offset temperature characteristic correction circuit
70d: gain temperature characteristic correction circuit
70e: automatic correction circuit
80a: first oscillator
80b: second oscillator
80c: memory
80d: temperature sensor
80e: interrupt generator
90: diagnosis circuit A
91: diagnosis circuit B
100, 100a, 100b, 100d, 100e, 100g, 100h, 100i, 100j, 100k, 100l: magnetic sensor
100a1: wire
100a2: wire
100a3: wire
100a4: wire
100b1: wire
100b2: wire
100b3: wire
100b4: wire
121, 122: magnetic resistance element
121a, 122a: first magnetic resistance element group
121b, 122b: second magnetic resistance element group
126a: first electrode group
126b: second electrode group
127a: third electrode group
127b: fourth electrode group
130, 130a, 130b: die pad
132, 132a, 132b: lead
134, 134a, 134b: wire
136: portion
138: sealing resin
142: detection target magnet
142a: first surface
142b: second surface
144: rotary shaft
146: bearing
150, 150b: rotation detection device
152: steering wheel
154: steering torque
156: torque sensor
158: motor
160: ECU
181: silicon substrate
183: first protective layer
184: second protective layer
185: MR layer
187: Ti layer
189: wiring layer
201a: first substrate
201b: second substrate
201b1: first portion
201b2: second portion
201c: third substrate
201c1: first portion
201c2: second portion
201d: fourth substrate
201d1: first portion
201d2: second portion
203: electrode
230, 260, 290, 292, 296: detection device
231: case
232: guide
233: detection target magnet
234: shaft
236: slit
251: coupling unit
261: case
262: guide
263: link mechanism
263a: supporter
263b: first movable body
263c: belt
263d: second movable body
264: shaft
266: slit
268: detection target magnet
270: gear wheel
272: shaft
274: substrate
281: supporter
291: tie bar
321: first surface
323: second surface
325: third surface
327: fourth surface
351: first resin
352: second resin
353: third resin

1. A magnetic sensor comprising:
a first magnetism detection element that outputs a first detection signal;
a second magnetism detection element that outputs a second detection signal; and
a detection circuit that receives the first detection signal and the second detection signal,
wherein the detection circuit converts the first detection signal and the second detection signal into a third signal, and corrects the first detection signal for each section in a ( 1/16n) period of the third signal, when n is a natural number.

2. The magnetic sensor according to claim 1, wherein the detection circuit performs an arctan operation on the first detection signal and the second detection signal to generate the third signal.

3. The magnetic sensor according to claim 1, wherein the first magnetism detection element and the second magnetism detection element are magnetic resistance films each comprising an NiFe alloy.

4. The magnetic sensor according to claim 1, wherein each of the first magnetism detection element and the second magnetism detection element includes
a substrate,
a magnetic resistance film that is provided on the substrate and comprises an NiFe alloy, and
a protective film that protects the magnetic resistance film.

5. The magnetic sensor according to claim 1, further comprising:
a silicon substrate; and
a silicon oxide layer provided on the silicon substrate, wherein
each of the first magnetism detection element and the second magnetism detection element is disposed on the silicon oxide layer, and
each of the first magnetism detection element and the second magnetism detection element is a magnetic resistance film comprising an NiFe alloy, and includes a protective layer covering the magnetic resistance film.

6. The magnetic sensor according to claim 5, wherein a ratio of a thickness to a width, in a section, of the magnetic resistance film is less than or equal to 1/1000.
